(19) United States
(12) Patent Application Publication
(10) Pub. No.: US 2023/0253372 A1
(43) Pub. Date: Aug. 10, 2023

(54) SEMICONDUCTOR DEVICE AND POWER CONVERSION DEVICE USING SAME

(71) Applicant: Mitsubishi Electric Corporation, Tokyo (JP)

(72) Inventors: Masashi SAKAI, Tokyo (JP); Masakazu TANI, Tokyo (JP)

(21) Appl. No.: 17/892,297

(22) Filed: Aug. 22, 2022

(30) Foreign Application Priority Data
Feb. 8, 2022 (JP) 2022-017649

(51) Int. Cl. H01L 25/07; H01L 23/31; H01L 23/373

(52) U.S. Cl. CPC H01L 25/072; H01L 23/3107; H01L 23/3735; H02M 7/003

(57) ABSTRACT

A semiconductor device includes a plurality of arms each including: a heat dissipation plate; a switching element; a metal terminal; and a sealing material, the metal terminals of the two specific arms adjacent to each other in the first direction has a first protruding portion which protrudes from a portion of the sealing material on one side in the second direction, the first protruding portion of one specific arm is arranged on a side closer to the other specific arm than a center portion in the first direction is, at the portion of the sealing material on the one side in the second direction, and the first protruding portion of the other specific arm is arranged on a side closer to the one specific arm than a center portion in the first direction is, at the portion of the sealing material on the one side in the second direction.

### BACKGROUND

The present disclosure relates to a semiconductor device and a power conversion device using the same.

Electrically powered vehicles, such as electric vehicles and plug-in hybrid vehicles, are equipped with power conversion devices for converting the power of high-voltage batteries. In power conversion devices, semiconductor devices that convert power through switching operation are used.

The following semiconductor device is disclosed (see, for example, Patent Document 1). The semiconductor device includes a semiconductor switching element electrically connected to a metal plate having heat dissipation property. The semiconductor switching element is connected to a main terminal forming a power circuit for power conversion and a control terminal connected to a control circuit that controls switching, by a method such as direct-lead-bonding (DLB) or wire bonding. The semiconductor switching element is sealed by a sealing material such as resin or gel. The main terminal and the control terminal that are connected to the same semiconductor switching element each protrude from one surface of the sealing material or different surfaces of the sealing material, and these terminals are aligned along the surface from which each terminal protrudes.

The disclosed semiconductor device includes a switching element arranged on one surface of a heat dissipation plate, and metal terminals connected to one surface of the switching element, and these components are sealed by a sealing material composed of resin. The metal terminals are a main terminal and a control terminal, a part of each of which protrudes from the sealing material. The main terminal protrudes from one surface of the sealing material and the surface of the sealing material opposite to the one surface. The control terminal protrudes from a surface different from the surfaces from which the main terminal protrudes. One semiconductor device is used for each of U, V, and W phases, so that three semiconductor devices are provided so as to be aligned with each other. The three semiconductor devices are aligned in the same direction such that side surfaces of the sealing materials from which the main terminals do not protrude are adjacent to each other, and the directions in which the main terminals of the respective semiconductor devices protrude are the same.

Moreover, since an increase in the output of a power conversion device is required, a power conversion device tends to be configured by using a plurality of semiconductor devices for each phase. In such a power conversion device, main terminals on the output sides of the plurality of semiconductor devices are connected to, for example, U, V, and W phases of a motor, respectively. In the case where two semiconductor devices connected in parallel are connected to each of the phases, since the electrical characteristics of each switching element originally have variations, even if a current flows through the two semiconductor devices at the same timing, the switching speed of the switching element in one semiconductor device may be faster, and the switching speed of the switching element in the other semiconductor device may be slower than the switching speed in the one semiconductor device. In this case, the switching timings in both switching elements are shifted from each other.

Furthermore, in the case where the lengths of the main terminals connected to the switching elements are different from each other, the inductances of the two semiconductor devices are different from each other, so that it is easier for a current to flow through one semiconductor device having lower inductance, and it is more difficult for a current to flow through the other semiconductor device having higher inductance. If the amount of the current in the switching element exceeds the allowable range due to a shift of the switching timing and an increase in the amount of the current in one semiconductor device due to an increase in the circuit inductance of the semiconductor device, the semiconductor device will be destroyed.
Patent Document 1: Japanese Laid-Open Patent Publication No. 2014-22579

In the structure of the semiconductor device in Patent Document 1 described above, the main terminals on the output sides, which are metal terminals, can be provided so as to be aligned in the same direction. However, in the case where a plurality of semiconductor devices are connected to each of the phases, the distance between the main terminals of the adjacent semiconductor devices is increased, so that the length of a wire between the adjacent semiconductor devices is lengthened, and the lengths of the main terminals become different from each other. Therefore, there is a problem that the circuit inductance of each semiconductor device is increased. In addition, since the length of the wire between the adjacent semiconductor devices is lengthened, there is a problem that the sizes of the semiconductor devices and the power conversion device using the semiconductor devices are increased.

### SUMMARY

Therefore, an object of the present disclosure is to provide a semiconductor device that suppresses an increase in the circuit inductance thereof, and provide a semiconductor device that suppresses an increase in the size thereof and a power conversion device using the semiconductor device.

A semiconductor device according to the present disclosure is a semiconductor device including a plurality of arms each including: a heat dissipation plate; one or more switching elements electrically connected to one surface of the heat dissipation plate; a metal terminal connected to a surface of each switching element on a side opposite to the heat dissipation plate side; and a sealing material sealing the heat dissipation plate, each switching element, and the metal terminal, wherein the heat dissipation plates of the plurality of arms are provided on a same plane so as to be aligned in a first direction which is a specific direction parallel to the same plane, a direction which is parallel to the same plane and orthogonal to the first direction is defined as a second direction, a direction orthogonal to the same plane is defined as a third direction, each of the metal terminals of the two specific arms adjacent to each other in the first direction has a first protruding portion which protrudes from a portion of the sealing material on one side in the second direction, the first protruding portion of one specific arm is arranged on a side closer to the other specific arm than a center portion in the first direction is, at the portion of the sealing material on the one side in the second direction, and the first protruding portion of the other specific arm is arranged on a side closer to the one specific arm than a center portion in the first direction is, at the portion of the sealing material on the one side in the second direction.

A power conversion device according to the present disclosure is a power conversion device including the semiconductor device according to the present disclosure, a control circuit unit controlling the semiconductor device, and a cooler thermally connected to the semiconductor device.

The semiconductor device according to the present disclosure includes the plurality of arms each including: the heat dissipation plate; the switching element electrically connected to the one surface of the heat dissipation plate; the metal terminal connected to the surface of the switching element on the side opposite to the heat dissipation plate side; and the sealing material sealing these components, the heat dissipation plates of the plurality of arms are provided on the same plane so as to be aligned in the first direction which is a specific direction parallel to the same plane, the direction which is parallel to the same plane and orthogonal to the first direction is defined as the second direction, each of the metal terminals of the two specific arms adjacent to each other in the first direction has the first protruding portion which protrudes from the portion of the sealing material on the one side in the second direction, the first protruding portion of the one specific arm is arranged on the side closer to the other specific arm than the center portion in the first direction is, at the portion of the sealing material on the one side in the second direction, and the first protruding portion of the other specific arm is arranged on the side closer to the one specific arm than the center portion in the first direction is, at the portion of the sealing material on the one side in the second direction. Therefore, the lengths of a wire connecting the first protruding portions of the respective two specific arms can be shortened, so that an increase in the circuit inductance between the two specific arms in the semiconductor device can be suppressed. In addition, since the length of the wire connecting the first protruding portions of the respective two specific arms is shortened, an increase in the size of the semiconductor device can be suppressed.

Since the power conversion device according to the present disclosure includes the semiconductor device according to the present disclosure, the control circuit unit controlling the semiconductor device, and the cooler thermally connected to the semiconductor device, the semiconductor device is configured such that the length of a wire connecting the first protruding portions of the two specific arms is shortened, and an increase in the size of the semiconductor device is suppressed, so that an increase in the size of the power conversion device using the semiconductor device can be suppressed.

### BRIEF DESCRIPTION OF THE DRAWINGS

FIG. 1 is a plan view showing the outer appearance of an arm of a semiconductor device according to a first embodiment;

FIG. 2 is a plan view schematically showing the configuration of the arm of the semiconductor device according to the first embodiment;

FIG. 3 is a side view showing a major part of the configuration of the arm of the semiconductor device according to the first embodiment;

FIG. 4 is a plan view schematically showing the configuration of the semiconductor device according to the first embodiment;

FIG. 5 is a simplified circuit diagram of the semiconductor device according to the first embodiment;

FIGS. 6A to 6C are simplified waveform diagrams of the semiconductor device according to the first embodiment;

FIG. 7 schematically shows the configuration of a power conversion device according to the first embodiment;

FIG. 8 is a plan view schematically showing the configuration of another semiconductor device according to the first embodiment;

FIG. 9 is a plan view schematically showing the configuration of still another semiconductor device according to the first embodiment;

FIG. 10 is a plan view showing the outer appearance of still another semiconductor device according to the first embodiment;

FIG. 11 is a plan view showing the outer appearance of still another semiconductor device according to the first embodiment;

FIG. 12 is a perspective view showing the outer appearance of a phase arm of a semiconductor device according to a second embodiment;

FIG. 13 is a perspective view schematically showing the configuration of the phase arm of the semiconductor device according to the second embodiment;

FIG. 14 is a plan view schematically showing the configuration of the phase arm of the semiconductor device according to the second embodiment;

FIG. 15 is a side view schematically showing the configuration of the phase arm of the semiconductor device according to the second embodiment;

FIG. 16 is a side view showing a main part of the configuration of the phase arm of the semiconductor device according to the second embodiment;

FIG. 17 is a plan view schematically showing the configuration of the semiconductor device according to the second embodiment;

FIG. 18 is a simplified circuit diagram of the semiconductor device according to the second embodiment;

FIG. 19 is a plan view showing the outer appearance of another semiconductor device according to the second embodiment;

FIG. 20 is a plan view schematically showing the configuration of a semiconductor device according to a third embodiment;

FIG. 21 is a plan view schematically showing the configuration of a semiconductor device according to a fourth embodiment; and

FIG. 22 is a plan view schematically showing the configuration of a semiconductor device according to a fifth embodiment.

### DETAILED DESCRIPTION OF THE EMBODIMENTS

Hereinafter, semiconductor devices and power conversion devices using the same according to embodiments of the present disclosure will be described with reference to the drawings. In the drawings, the same or corresponding members and parts are denoted by the same reference characters to give description.

### First Embodiment

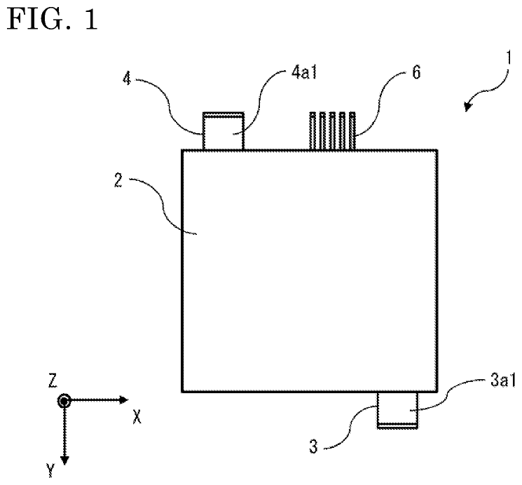

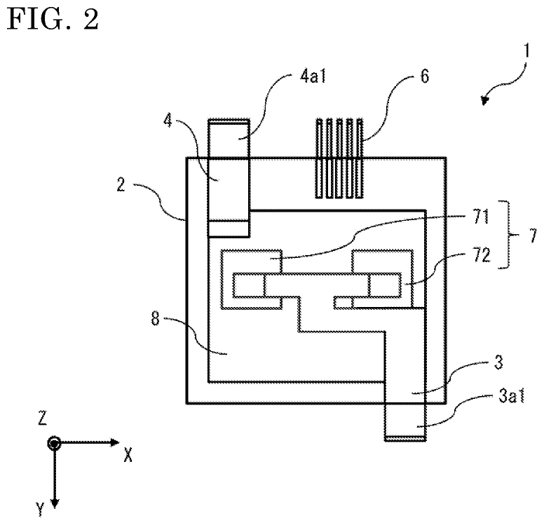

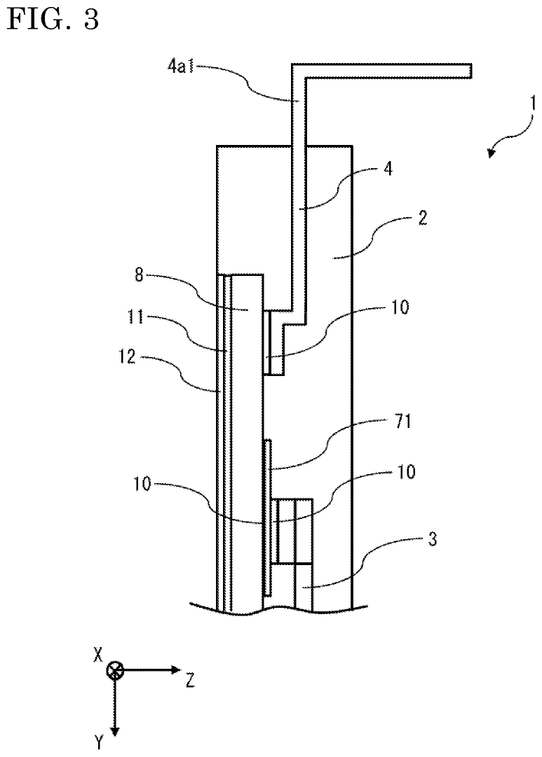

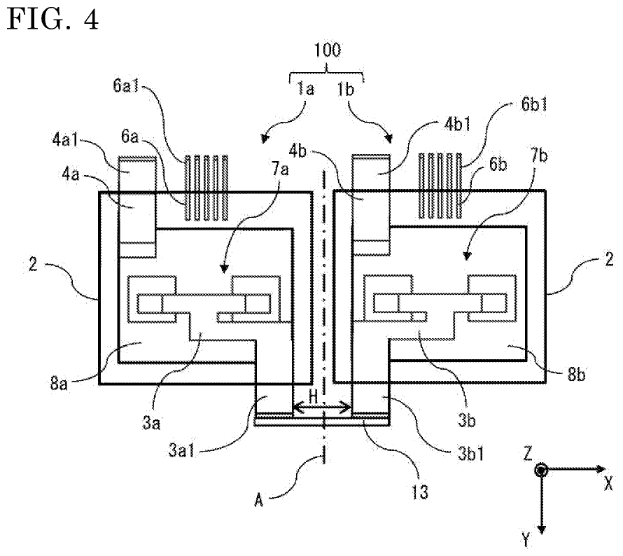

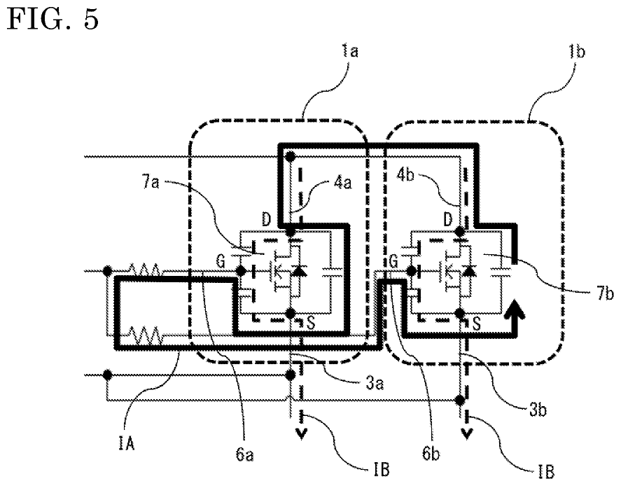

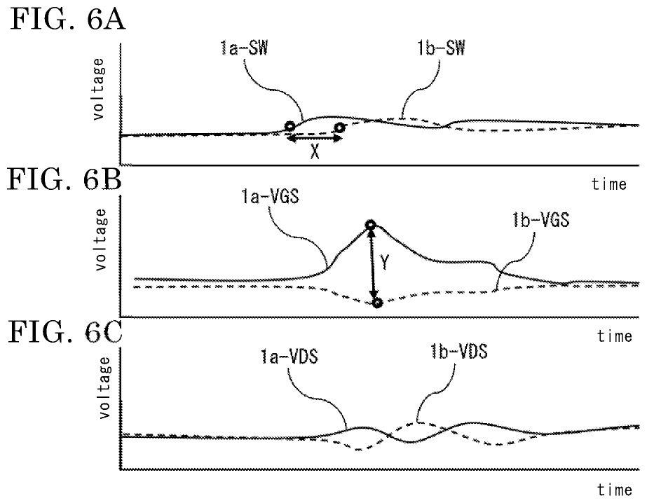

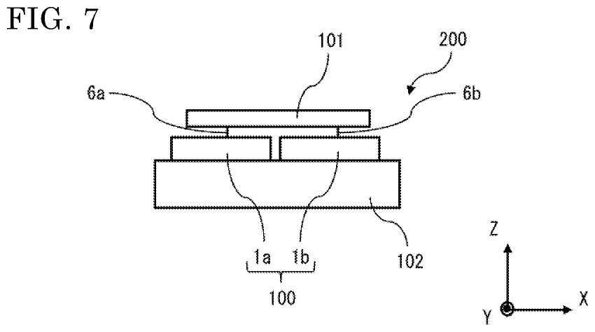

FIG. 1 is a plan view showing the outer appearance of an arm 1 of a semiconductor device 100 according to a first embodiment; FIG. 2 is a plan view schematically showing the configuration of the arm 1 of the semiconductor device 100, wherein a part of a sealing material 2 is removed; FIG. 3 is a side view showing a main part of the configuration of the arm 1 of the semiconductor device 100, as viewed from the left side of FIG. 2, wherein a part of the sealing material 2 is removed; FIG. 4 is a plan view schematically showing the configuration of the semiconductor device 100, wherein a part of each sealing material 2 is removed; FIG. 5 is a simplified circuit diagram of the semiconductor device 100; FIGS. 6A to 6C are simplified waveform diagrams of the semiconductor device 100; and FIG. 7 schematically shows the configuration of a power conversion device 200. The semiconductor device 100 is a device that includes a plurality of arms 1 and converts power through switching operations of switching elements 7 included in the arms 1. The power conversion device 200 is a device that includes the semiconductor device 100 and converts an input current from DC to AC or from AC to DC, or an input voltage into a different voltage.

<Arms 1>

Each arm 1 included in the semiconductor device 100 will be described. The arm 1 is generally in the form called a 1-in-1 module. As shown in FIG. 1, an N terminal 3 which is a metal terminal, a P terminal 4 which is a heat dissipation plate metal terminal, and a control terminal 6 are provided in the arm 1 so as to protrude from the sealing material 2 to the outside. In the present embodiment, the P terminal 4 and the control terminal 6 protrude from the same side surface of the sealing material 2 to the outside, and the N terminal 3 protrudes from a side surface opposite to the side surface from which the P terminal 4 and the control terminal 6 protrude. The protruding portion of the N terminal 3 is a first protruding portion 3a1, and the protruding portion of the P terminal 4 is a P terminal protruding portion 4a1. The surfaces of the sealing material 2 from which the respective terminals protrude are not limited thereto. These terminals are terminals connected to an external device. The sealing material 2 is provided in a rectangular parallelepiped shape, but the shape of the sealing material 2 is not limited thereto. The heights in a Z direction at which the respective terminals are provided are the same or different heights according to the terminal arrangement of the external device to which the terminals are connected, etc. The portion on the protruding side of each terminal is bent in the Z direction, and connected to the external device at the bent portion.

As shown in FIG. 2, the arm 1 includes a heat dissipation plate 8, the switching element 7, the N terminal 3, the P terminal 4, the control terminal 6, and the sealing material 2 which seals the heat dissipation plate 8, the switching element 7, the N terminal 3, the P terminal 4, and the control terminal 6. One or more switching elements 7 are electrically connected to one surface of the heat dissipation plate 8. In the present embodiment, two switching elements 71 and 72 connected in parallel are provided, but the number of switching elements 7 is not limited thereto. The N terminal 3 is connected to the surface of each switching element 7 on the side opposite to the heat dissipation plate 8 side. The P terminal 4 is connected to one surface of the heat dissipation plate 8. The control terminal 6 is connected to the switching element 7.

As shown in FIG. 3, the arm 1 includes a heat dissipation sheet 12 which is thermally connected to the other surface of the heat dissipation plate 8 via an insulating plate 11 which is an insulating layer. The surface of the heat dissipation sheet 12 on the side opposite to the heat dissipation plate 8 side is exposed from the sealing material 2. The insulating plate 11 is, for example, a plate made of ceramics. The insulating layer is not limited to the insulating plate 11, and may be an insulating sheet. The heat dissipation sheet 12 is, for example, a metal plate made of copper. With this structure, heat generated in the switching element 7 can be easily dissipated from the heat dissipation sheet 12 to the outside. In addition, since the heat dissipation sheet 12 and the heat dissipation plate 8 are connected to each other via the insulating plate 11, the reliability of insulation between the heat dissipation sheet 12 and the heat dissipation plate 8 can be ensured.

The sealing material 2 is, for example, mold resin or silicone gel. In the present embodiment, the semiconductor device 100 is formed through transfer molding using mold resin, but is not limited thereto, and a sealing material such as silicone gel may be used. In the case of sealing with silicone gel, for example, the silicone gel is injected into a resin case in which the switching element 7, etc., are housed. In the case of using mold resin, the arm 1 can withstand high temperatures. In addition, since water, dust, etc., do not enter the inside from the outside, the internal environment can be easily maintained. In addition, the inside can be protected from external force such as vibration. In the case where silicone gel is used, since the silicone gel is transparent, it is possible to visually inspect the inside of the arm 1 after sealing, so that the inside of the arm 1 can be easily inspected.

The heat dissipation plate 8 is made of metal such as copper or aluminum that is excellent in thermal conductivity and has electric conductivity. In the present embodiment, the heat dissipation plate 8 is made in a rectangular shape, but the shape of the heat dissipation plate 8 is not limited to a rectangular shape. The heat dissipation plate 8 is, for example, a heat spreader made of copper. The material of the heat dissipation plate 8 is not limited thereto, and the heat dissipation plate 8 may be made of another substrate material such as a direct bonded copper (DBC) substrate obtained by joining, to a base plate made of copper, a ceramic insulating substrate which is an insulating material having metal foil joined thereto by brazing or the like.

The joining material electrically connecting the switching element 7 and the heat dissipation plate 8 is, for example, Ag or solder. The terminal, of the switching element 7, which is connected to the heat dissipation plate 8 is a drain terminal (not shown). The heat dissipation plate 8 and the switching element 71 are electrically and thermally connected to each other by solder 10 as shown in FIG. 3. The connection between the heat dissipation plate 8 and the switching element 7 is not limited to connection by solder, and a material having characteristics of high thermal conductivity and low electric resistance may be used. Thus, for example, an Ag sinter which is a paste material containing silver as a main component may be used. In the case where solder is used as the joining material, since solder is a common joining material and thus inexpensive, the cost of the semiconductor device 100 can be reduced. In the case where Ag is used as the joining material, the semiconductor device 100 can be used at a higher temperature than that in the case where solder is used, so that the reliability of the semiconductor device 100 in use at high temperatures can be improved. Heat generated in the switching element 7 is dissipated to the surroundings via the heat dissipation plate 8, so that the switching element 7 is effectively cooled.

The respective terminals such as the N terminal 3, the P terminal 4, and the control terminal 6 are made of metal such as copper or aluminum that has electric conductivity. The N terminal 3 and the switching element 7 are electrically connected to each other by solder 10. The terminal, of the switching element 7, which is connected to the N terminal 3 is a source terminal (not shown). The P terminal 4 and the heat dissipation plate 8 are electrically connected to each other by solder 10. The control terminal 6 and the switching element 7 are electrically connected to each other by a bonding wire (not shown). The terminal, of the switching element 7, which is connected to the control terminal 6 is a gate terminal (not shown). The bonding wire is, for example, a wire made of aluminum, but is not limited thereto, and may be another conductor such as a ribbon made of copper. A plurality of control terminals 6 are provided, and another control terminal 6 is connected to, for example, a thermistor (not shown) provided on the heat dissipation plate 8.

During production of the arm 1, before sealing by the sealing material 2, the portions, of the N terminal 3, the P terminal 4, and the control terminal 6, which protrude from the sealing material 2 are connected to each other, and a lead frame is formed thereon. The N terminal 3, the P terminal 4, and the control terminal 6 are sealed by the sealing material 2 in a state of being supported by the same lead frame. After sealing, the N terminal 3, the P terminal 4, and the control terminal 6 that are independent of each other are formed by cutting the lead frame portions thereof. The N terminal 3, the P terminal 4, and the control terminal 6 are produced by such a general production process for a semiconductor device. In the sealing process, the lead frame is held between an upper die and a lower die of a resin molding mold.

As each switching element 7, a power control semiconductor element such as a metal oxide semiconductor field effect transistor (MOSFET) or insulated gate bipolar transistor (IGBT), a flyback diode, or the like is used. The switching element 7 is not limited thereto, and may be another switching element such as a bipolar transistor. In the present embodiment, a MOSFET is used, and the parasitic diode of the MOSFET is used as a flyback diode. However, in the case of, for example, using switching elements such as IGBTs not having parasitic diodes, flyback diodes may be added in parallel. The switching elements 7 are formed in a semiconductor substrate made of a material such as silicon carbide, silicon, or gallium nitride.

<Semiconductor Device 100>

The semiconductor device 100 including the plurality of arms 1 will be described. Since an increase in the output of a semiconductor device is required, a semiconductor device may be configured by using a plurality of arms, which are connected in parallel, for each phase of an electromagnetic induction machine which is a load. The heat dissipation plates 8 of the plurality of arms 1 are provided on the same plane so as to be aligned in a first direction which is a specific direction parallel to the same plane. In the present embodiment, as shown in FIG. 4, the semiconductor device 100 includes arms 1a and 1b which are two specific arms adjacent to each other in the first direction. The number of arms included in the semiconductor device 100 is not limited to two. Heat dissipation plates 8a and 8b of the arms 1a and 1b are provided so as to be aligned in the first direction. Here, a direction which is parallel to the same plane and orthogonal to the first direction is defined as a second direction, and a direction that is orthogonal to the same plane is defined as a third direction. In the drawings, the first direction is an X direction, the second direction is a Y direction, the third direction is a Z direction, the direction indicated by an arrow corresponds to one side, and the side opposite to the direction indicated by the arrow is another side.

N terminals 3a and 3b of the arms 1a and 1b have first protruding portions 3a1 and 3b1 which protrude from portions of the sealing materials 2 on one side in the second direction. The first protruding portion 3a1 of the arm 1a which is one specific arm is arranged on the side closer to the arm 1b, which is the other specific arm, than a center portion in the first direction is, at the portion of the sealing material 2 on the one side in the second direction. The first protruding portion 3b1 of the arm 1b is arranged on the side closer to the arm 1a than a center portion in the first direction is, at the portion of the sealing material 2 on the one side in the second direction. The first protruding portion 3a1 and the first protruding portion 3b1 are connected to each other by a connection terminal 13. The first protruding portions 3a1 and 3b1 and the connection terminal 13 are connected to each other, for example, by TIG welding. With this configuration, a distance H which is the length of a wire connecting the first protruding portion 3a1 and the first protruding portion 3b1 can be shortened. Since the distance H can be shortened, an increase in the circuit inductance of the semiconductor device 100 can be suppressed.

Moreover, in the present embodiment, the first protruding portion 3a1 of the arm 1a and the first protruding portion 3b1 of the arm 1b are arranged so as to be line-symmetric about a center line A between the arms 1a and 1b. With this configuration, the distance from the center line A to the first protruding portion 3a1 and the distance from the center line A to the first protruding portion 3b1 are equal to each other, and the lengths of the wires at these portions are equal to each other, so that an increase in the circuit inductance of the semiconductor device 100 can be further suppressed.

Moreover, in the present embodiment, the first protruding portion 3a1 of the arm 1a and the first protruding portion 3b1 of the arm 1b protrude from the portions of the sealing materials 2 on the one side in the second direction, toward the one side in the second direction. With this configuration, since the N terminals 3a and 3b do not protrude between the arm 1a and the arm 1b, the interval between the arm 1a and the arm 1b can be decreased, so that the distance H can be shortened. Since the distance H can be shortened, an increase in the circuit inductance of the semiconductor device 100 can be suppressed. The direction in which the first protruding portions 3a1 and 3b1 protrude is not limited to the one side in the second direction, and may be the third direction. In the case where the first protruding portions 3a1 and 3b1 protrude in the third direction as well, the interval between the arm 1a and the arm 1b can be decreased. In addition, since the interval between the arm 1a and the arm 1b is decreased and the N terminals 3a and 3b do not protrude from both sides in the first direction, an increase in the size of the semiconductor device 100 can be suppressed.

P terminals 4a and 4b of the arms 1a and 1b have P terminal protruding portions 4a1 and 4b1 which are heat dissipation plate protruding portions which protrude from portions of the sealing materials 2 on the other side in the second direction. The P terminal protruding portions 4a1 and 4b1 protrude from the portions of the sealing materials 2 on the other side in the second direction, toward the other side in the second direction or in the third direction. In the present embodiment, the P terminal protruding portions 4a1 and 4b1 protrude toward the other side in the second direction. Control terminals 6a and 6b have control terminal protruding portions 6a1 and 6b1 which protrude from the portions of the sealing materials 2 on the other side in the second direction. The control terminal protruding portions 6a1 and 6b1 protrude from the portions of the sealing materials 2 on the other side in the second direction, toward the other side in the second direction or in the third direction. In the present embodiment, the control terminals 6a and 6b protrude toward the other side in the second direction. With this configuration, since the P terminals 4a and 4b and the control terminals 6a and 6b do not protrude between the arm 1a and the arm 1b, the interval between the arm 1a and the arm 1b can be decreased, so that the distance H can be shortened. Since the distance H can be shortened, an increase in the circuit inductance of the semiconductor device 100 can be suppressed. In addition, since the interval between the arm 1a and the arm 1b is decreased and the P terminals 4a and 4b and the control terminals 6a and 6b do not protrude from both sides in the first direction, an increase in the size of the semiconductor device 100 can be suppressed.

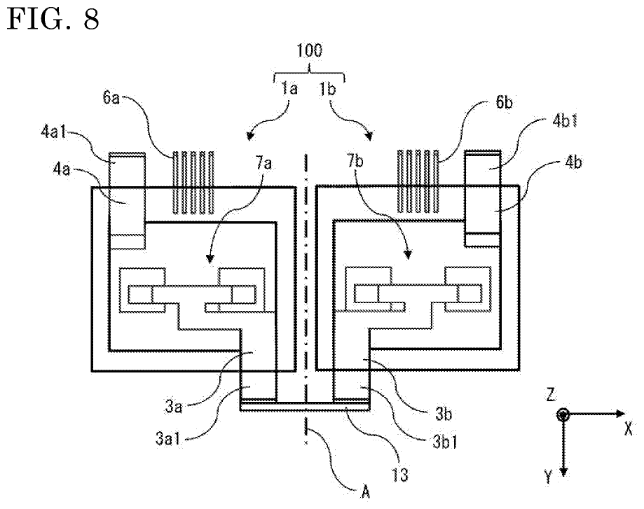

The arrangement of the P terminals 4a and 4b is not limited to the arrangement shown in FIG. 4 and may be the arrangement shown in FIG. 8. FIG. 8 is a plan view schematically showing the configuration of another semiconductor device 100, wherein a part of each sealing material 2 is removed. The P terminal 4a of the arm 1a and the P terminal 4b of the arm 1b are arranged so as to be line-symmetric about the center line A between the arms 1a and 1b. The control terminal 6a of the arm 1a and the control terminal 6b of the arm 1b are arranged so as to be line-symmetric about the center line A between the arms 1a and 1b. With this configuration, the wire length from the P terminal 4a to the N terminal 3a in the arm 1a and the wire length from the P terminal 4b to the N terminal 3b in the arm 1b can be equal to each other. Since the wire lengths in the arm 1a and the arm 1b are equal to each other, an increase in the circuit inductance of the semiconductor device 100 can be suppressed. In addition, even if the switching characteristics of the switching elements 7a and 7b are different from each other, the influence on the power conversion device 200 described later is reduced by suppressing an increase in the circuit inductance, so that the reliability of the power conversion device 200 can be improved.

The reason for suppressing an increase in the circuit inductance will be described with reference to FIG. 5 and FIGS. 6A to 6C. In FIG. 5, a current path IA is indicated by a solid-line arrow, and current paths IB are indicated by broken-line arrows. In the arm 1a, the current path IB, which is a current path extending from the P terminal 4a via a drain terminal D of the switching element 7a, passing through a source terminal S of the switching element 7a, and leading to the N terminal 3a, is an ideal current path. Similarly, in the arm 1b, the current path IB, which is a current path extending from the P terminal 4b via a drain terminal D of the switching element 7b, passing through a source terminal S of the switching element 7b, and leading to the N terminal 3b, is an ideal current path. Each gate terminal G is connected to a control circuit unit included in the power conversion device 200 described later.

However, if the arrangements, the lengths, or the thicknesses of internal wires in the arm 1a and the arm 1b are different from each other, a difference in circuit inductance occurs. When a difference in circuit inductance occurs, the switching timings of the arm 1a and the arm 1b are shifted from each other. In addition, when there are variations in a gate threshold voltage (Vth) of each switching element 7, the switching timings of the arm 1a and the arm 1b are shifted from each other due to the variations in Vth.

FIG. 6A shows an example of the switching timings of the arm 1a and the arm 1b, a solid line is for the arm 1a, and a broken line is for the arm 1b. FIG. 6B shows an example of changes over time in gate-source voltages (VGS) of the arm 1a and the arm 1b, a solid line is for the arm 1a, and a broken line is for the arm 1b. FIG. 6C shows an example of changes over time in drain-source voltages (VDS) of the arm 1a and the arm 1b, a solid line is for the arm 1a, and a broken line is for the arm 1b. In FIG. 6A, the arm 1a and the arm 1b perform switching at times indicated by circles, respectively. In the example shown in FIG. 6A, a current more easily flows in the arm 1a than in the arm 1b, so that the arm 1a performs switching at an earlier timing than the arm 1b, and the arm 1b performs switching after a time X.

When the switching timings of the arm 1a and the arm 1b are shifted from each other as described above, the current path IB shown in FIG. 5 is not provided. Even when the switching element 7a of the arm 1a is turned on and a switching waveform 1a-SW of the arm 1a rises as in FIG. 6A, if the time X in which the switching element 7b of the arm 1b is off and a switching waveform 1b-SW of the arm 1b does not rise occurs, the VDS in the arm 1a is higher than the VDS in the arm 1b as shown in FIG. 6C. At this time, since a current flows through the current path IA, the switching element 7a is charged, so that a rise in the gate voltage of the arm 1a occurs. When a rise in the gate voltage occurs, the VGS of the arm 1a becomes higher than that of the arm 1b by Y as shown in FIG. 6B, so that the semiconductor device 100 exceeds the withstanding voltage and becomes destroyed.

Owing to the above-described configuration, the distance H which is the length of the wire connecting the first protruding portion 3a1 and the first protruding portion 3b1 can be shortened, so that an increase in the circuit inductance between the arm 1a and the arm 1b in the semiconductor device 100 can be suppressed. Since an increase in the circuit inductance is suppressed, a current easily flows through the N terminals 3a and 3b, so that the current flowing through the current path IA is reduced. Since the current flowing through the current path IA is reduced, the switching element 7a is prevented from being charged, so that the semiconductor device 100 is prevented from being destroyed. Since the semiconductor device 100 is prevented from being destroyed, the reliability of the semiconductor device 100 is improved. In addition, since the distance H is shortened, an increase in the size of the semiconductor device 100 can be suppressed.

<Power Conversion Device 200>

The power conversion device 200 using the semiconductor device 100 will be described. As shown in FIG. 7, the power conversion device 200 includes the above-described semiconductor device 100, a control circuit unit 101 which controls the semiconductor device 100, and a cooler 102 which is thermally connected to the semiconductor device 100. The semiconductor device 100 is composed of, for example, the arm 1a and the arm 1b. The control circuit unit 101 and the arm 1a are connected to each other by the control terminal 6a, and the control circuit unit 101 and the arm 1b are connected to each other by the control terminal 6b. The semiconductor device 100 is cooled by the cooler 102. The cooler 102 is, for example, a heat sink composed of a cooling plate. The cooler 102 may be configured such that a cooling fluid flows therein. In the case where the semiconductor device 100 includes the heat dissipation sheet 12, when the heat dissipation sheet 12 and the cooler 102 are thermally connected to each other, the semiconductor device 100 can be efficiently cooled by the cooler 102. Since the above-described semiconductor device 100 is configured such that the distance H is shortened, an increase in the size of the semiconductor device 100 is suppressed, so that an increase in the size of the power conversion device 200 using the semiconductor device 100 can be suppressed.

<First Modification>

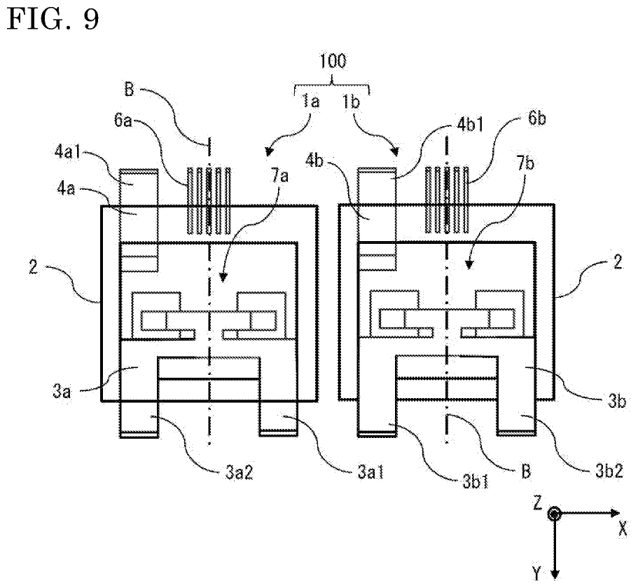

A modification of the semiconductor device 100 will be described. FIG. 9 is a plan view schematically showing the configuration of still another semiconductor device 100 according to the first embodiment, wherein a part of each sealing material 2 is removed. Similar to FIG. 4, the semiconductor device 100 includes arms 1a and 1b which are two specific arms adjacent to each other in the first direction. The N terminal 3a of the arm 1a has a first protruding portion 3a1 and a second protruding portion 3a2 into which the N terminal 3a branches inside the sealing material 2 and which protrude from the portion of the sealing material 2 on the one side in the second direction. The N terminal 3b of the arm 1b has a first protruding portion 3b1 and a second protruding portion 3b2 into which the N terminal 3b branches inside the sealing material 2 and which protrude from the portion of the sealing material 2 on the one side in the second direction. The first protruding portions 3a1 and 3b1 are arranged in the same manner as in the configuration shown in FIG. 4. The second protruding portion 3a2 of the arm 1a is arranged on the side farther from the arm 1b than the center portion in the first direction is, at the portion of the sealing material 2 on the one side in the second direction. The second protruding portion 3b2 of the arm 1b is arranged on the side farther from the arm 1a than the center portion in the first direction is, at the portion of the sealing material 2 on the one side in the second direction.

With this configuration, the cross-sectional areas of wires connecting the N terminals 3a and 3b to the outside can be increased. Therefore, as compared to the configuration shown in FIG. 4, an increase in the circuit inductance between the arm 1a and the arm 1b in the semiconductor device 100 can be suppressed. Since an increase in the circuit inductance is suppressed, a current easily flows through the N terminals 3a and 3b, so that the current flowing through the current path IA shown in FIG. 5 is reduced. Since the current flowing through the current path IA is reduced, the switching elements 7a and 7b are prevented from being charged, so that the semiconductor device 100 is prevented from being destroyed. Since the semiconductor device 100 is prevented from being destroyed, the reliability of the semiconductor device 100 is improved. In addition, since the cross-sectional areas of the wires are increased, heat generation in the N terminals 3a and 3b during current conduction can be suppressed.

Moreover, in the present embodiment, in the arm 1a, the first protruding portion 3a1 and the second protruding portion 3a2 are arranged so as to be line-symmetric about a center line B in the first direction of the arm 1a, and, in the arm 1b, the first protruding portion 3b1 and the second protruding portion 3b2 are arranged so as to be line-symmetric about a center line B in the first direction of the arm 1b. With this configuration, the distance from the center line B to the first protruding portion 3a1 and the distance from the center line B to the second protruding portion 3a2 are equal to each other, and the lengths of the wires at these portions are equal to each other, so that an increase in the circuit inductance of the semiconductor device 100 can be further suppressed; and the distance from the center line B to the first protruding portion 3b1 and the distance from the center line B to the second protruding portion 3b2 are equal to each other, and the lengths of the wires at these portions are equal to each other, so that an increase in the circuit inductance of the semiconductor device 100 can be further suppressed.

<Second Modification>

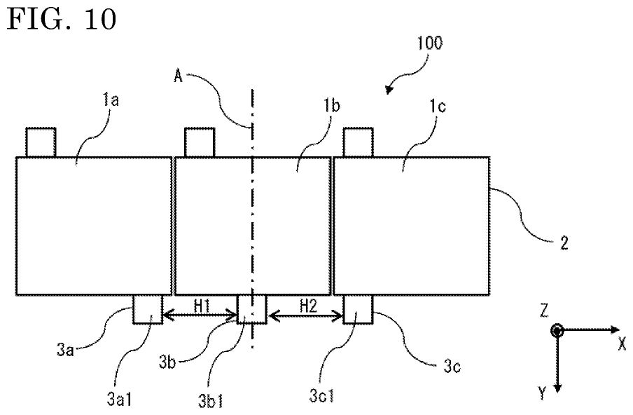

Another modification of the semiconductor device 100 will be described. FIG. 10 is a plan view showing the outer appearance of still another semiconductor device 100 according to the first embodiment, wherein each control terminal is not shown. In the second modification, the semiconductor device 100 includes arms 1a, 1b, and 1c which are three specific arms adjacent to each other in the first direction. The specific arm on the one side in the first direction is the arm 1a, the specific arm on the other side in the first direction is the arm 1c, and the specific arm at the center is the arm 1b. The N terminals 3a, 3b, and 3c of the arms 1a, 1b, and 1c have first protruding portions 3a1, 3b1, and 3c1 which protrude from the portions of the sealing materials 2 on the one side in the second direction.

The first protruding portion 3a1 of the arm 1a is arranged on the side closer to the arm 1b than the center portion in the first direction is, at the portion of the sealing material 2 on the one side in the second direction. The first protruding portion 3c1 of the arm 1c is arranged on the side closer to the arm 1b than the center portion in the first direction is, at the portion of the sealing material 2 on the one side in the second direction. The first protruding portion 3b1 of the arm 1b is arranged at the center portion in the first direction at the portion of the sealing material 2 on the one side in the second direction. With this configuration, a distance H1 which is the length of a wire connecting the first protruding portion 3a1 and the first protruding portion 3b1 and a distance H2 which is the length of a wire connecting the first protruding portion 3b1 and the first protruding portion 3c1 can be shortened. Since the distance H1 and the distance H2 can be shortened, an increase in the circuit inductance of the semiconductor device 100 can be suppressed.

Moreover, in the present embodiment, the first protruding portion 3a1 of the arm 1a and the first protruding portion 3c1 of the arm 1c are arranged so as to be line-symmetric about a center line A in the first direction of the arm 1b, and the first protruding portion 3b1 of the arm 1b is arranged on the center line A. With this configuration, the distance H1 which is the length of the wire connecting the first protruding portion 3a1 and the first protruding portion 3b1 and the distance H2 which is the length of the wire connecting the first protruding portion 3b1 and the first protruding portion 3c1 can be equal to each other. Since the distance H1 and the distance H2 are equal to each other, an increase in the circuit inductance of the semiconductor device 100 can be further suppressed.

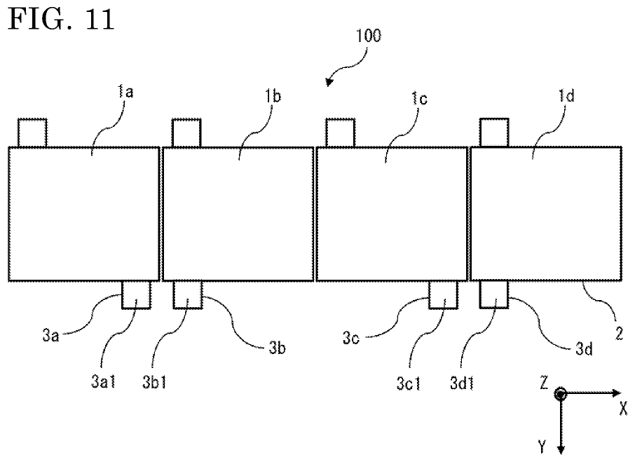

FIG. 11 is a plan view showing the outer appearance of still another semiconductor device 100 according to the first embodiment. In FIG. 11, the semiconductor device 100 includes arms 1a, 1b, 1c, and 1d which are four specific arms adjacent to each other in the first direction. The N terminals 3a, 3b, 3c, and 3d of the arms 1a, 1b, 1c, and 1d have first protruding portions 3a1, 3b1, 3c1, and 3d1 which protrude from the portions of the sealing materials 2 on the one side in the second direction. In the case where four arms are provided so as to be aligned in the first direction, the semiconductor devices 100 shown in FIG. 4 are aligned in the first direction as shown in FIG. 11. With this configuration, an increase in the circuit inductance between the arm 1a and the arm 1b can be suppressed, and an increase in the circuit inductance between the arm 1c and the arm 1d can be suppressed.

As described above, the semiconductor device 100 according to the first embodiment includes the plurality of arms 1 each including: the heat dissipation plate 8; the switching element 7 electrically connected to one surface of the heat dissipation plate 8; the N terminal 3 connected to the surface of the switching element 7 on the side opposite to the heat dissipation plate 8 side; and the sealing material 2 sealing these components, the heat dissipation plates 8 of the plurality of arms 1 are provided on the same plane so as to be aligned in the first direction which is a specific direction parallel to the same plane, the direction which is parallel to the same plane and orthogonal to the first direction is defined as the second direction, the N terminals 3 of the two specific arms 1a and 1b adjacent to each other in the first direction have the first protruding portions 3a1 and 3b1 which protrude from the portions of the sealing materials 2 on the one side in the second direction, respectively, the first protruding portion 3a1 of the one specific arm 1a is arranged on the side closer to the other specific arm 1b than the center portion in the first direction is, at the portion of the sealing material 2 on the one side in the second direction, and the first protruding portion 3b1 of the other specific arm 1b is arranged on the side closer to the one specific arm 1a than the center portion in the first direction is, at the portion of the sealing material 2 on the one side in the second direction. Therefore, the distance H which is the length of the wire connecting the first protruding portion 3a1 and the first protruding portion 3b1 can be shortened, so that an increase in the circuit inductance between the arm 1a and the arm 1b in the semiconductor device 100 can be suppressed. In addition, since the distance H is shortened, an increase in the size of the semiconductor device 100 can be suppressed.

In the case where the first protruding portion 3a1 of the arm 1a and the first protruding portion 3b1 of the arm 1b are arranged so as to be line-symmetric about the center line A between the arms 1a and 1b, the distance from the center line A to the first protruding portion 3a1 and the distance from the center line A to the first protruding portion 3b1 are equal to each other, and the lengths of the wires at these portions are equal to each other, so that an increase in the circuit inductance of the semiconductor device 100 can be further suppressed.

In the case where the first protruding portions 3a1 and 3b1 of the two specific arms 1a and 1b respectively protrude from the portions of the sealing materials 2 on the one side in the second direction, toward the one side in the second direction or in the third direction, since the N terminals 3a and 3b do not protrude between the arm 1a and the arm 1b, the interval between the arm 1a and the arm 1b can be decreased, so that the distance H is shortened and an increase in the circuit inductance of the semiconductor device 100 can be suppressed. In addition, since the interval between the arm 1a and the arm 1b is decreased and the N terminals 3a and 3b do not protrude from both sides in the first direction, an increase in the size of the semiconductor device 100 can be suppressed.

In the case where the N terminals 3a and 3b of the two specific arms 1a and 1b have the first protruding portions 3a1 and 3b1 and the second protruding portions 3a2 and 3b2 which protrude from the portions of the sealing materials 2 on the one side in the second direction, the second protruding portion 3a2 of the arm 1a is arranged on the side farther from the arm 1b than the center portion in the first direction is, at the portion of the sealing material 2 on the one side in the second direction, and the second protruding portion 3b2 of the arm 1b is arranged on the side farther from the arm 1a than the center portion in the first direction is, at the portion of the sealing material 2 on the one side in the second direction, the cross-sectional areas of the wires connecting the N terminals 3a and 3b to the outside can be increased, so that an increase in the circuit inductance between the arm 1a and the arm 1b in the semiconductor device 100 can be suppressed. In addition, since the cross-sectional areas of the wires are increased, heat generation in the N terminals 3a and 3b during current conduction can be suppressed.

In the case where, in the arm 1a, the first protruding portion 3a1 and the second protruding portion 3a2 are arranged so as to be line-symmetric about the center line B in the first direction of the arm 1a, and, in the arm 1b, the first protruding portion 3b1 and the second protruding portion 3b2 are arranged so as to be line-symmetric about the center line B in the first direction of the arm 1b, the distance from the center line B to the first protruding portion 3a1 and the distance from the center line B to the second protruding portion 3a2 are equal to each other, and the lengths of the wires at these portions are equal to each other, so that an increase in the circuit inductance of the semiconductor device 100 can be further suppressed; and the distance from the center line B to the first protruding portion 3b1 and the distance from the center line B to the second protruding portion 3b2 are equal to each other, and the lengths of the wires at these portions are equal to each other, so that an increase in the circuit inductance of the semiconductor device 100 can be further suppressed.

In the case where the two specific arms 1a and 1b include the P terminals 4a and 4b and the control terminals 6a and 6b, respectively, the P terminal protruding portions 4a1 and 4b1 protrude from the portions of the sealing materials 2 on the other side in the second direction, toward the other side in the second direction or in the third direction, and the control terminal protruding portions 6a1 and 6b1 protrude from the portions of the sealing materials 2 on the other side in the second direction, toward the other side in the second direction or in the third direction, since the P terminals 4a and 4b and the control terminals 6a and 6b do not protrude between the arm 1a and the arm 1b, an interval between the arm 1a and the arm 1b can be decreased, so that the distance H can be shortened and an increase in the circuit inductance of the semiconductor device 100 can be suppressed. In addition, since the interval between the arm 1a and the arm 1b is decreased and the P terminals 4a and 4b and the control terminals 6a and 6b do not protrude from both sides in the first direction, an increase in the size of the semiconductor device 100 can be suppressed.

In the case where the P terminal 4a of the arm 1a and the P terminal 4b of the arm 1b are arranged so as to be line-symmetric about the center line A between the arms 1a and 1b, and the control terminal 6a of the arm 1a and the control terminal 6b of the arm 1b are arranged so as to be line-symmetric about the center line A between the arms 1a and 1b, the length of the wire from the P terminal 4a to the N terminal 3a in the arm 1a and the length of the wire from the P terminal 4b to the N terminal 3b in the arm 1b can be equal to each other, and the lengths of the wires in the arm 1a and the arm 1b are equal to each other, so that an increase in the circuit inductance of the semiconductor device 100 can be suppressed.

In the case where: the semiconductor device 100 includes the three specific arms 1a, 1b, and 1c adjacent to each other in the first direction; and when the specific arm on the one side in the first direction is the arm 1a, the specific arm on the other side in the first direction is the arm 1c, and the specific arm at the center is the arm 1b, the first protruding portion 3a1 of the arm 1a is arranged on the side closer to the arm 1b than the center portion in the first direction is, at the portion of the sealing material 2 on the one side in the second direction, the first protruding portion 3c1 of the arm 1c is arranged on the side closer to the arm 1b than the center portion in the first direction is, at the portion of the sealing material 2 on the one side in the second direction, and the first protruding portion 3b1 of the arm 1b is arranged at the center portion in the first direction at the portion of the sealing material 2 on the one side in the second direction, the distance H1 which is the length of the wire connecting the first protruding portion 3a1 and the first protruding portion 3b1 and the distance H2 which is the length of the wire connecting the first protruding portion 3b1 and the first protruding portion 3c1 can be shortened, so that an increase in the circuit inductance of the semiconductor device 100 can be suppressed.

In the case where the first protruding portion 3a1 of the arm 1a and the first protruding portion 3c1 of the arm 1c are arranged so as to be line-symmetric about the center line A in the first direction of the arm 1b, and the first protruding portion 3b1 of the arm 1b is arranged on the center line A, the distance H1 which is the length of the wire connecting the first protruding portion 3a1 and the first protruding portion 3b1 and the distance H2 which is the length of the wire connecting the first protruding portion 3b1 and the first protruding portion 3c1 can be equal to each other, so that an increase in the circuit inductance of the semiconductor device 100 can be further suppressed.

In the case where the semiconductor device 100 includes the heat dissipation sheet 12 which is thermally connected to the other surface of the heat dissipation plate 8 via the insulating plate 11, and the surface of the heat dissipation sheet 12 on the side opposite to the heat dissipation plate 8 side is exposed from the sealing material 2, heat generated in the switching element 7 can be easily dissipated from the heat dissipation sheet 12 to the outside. In addition, in the case where the sealing material 2 is composed of mold resin, the semiconductor device 100 can withstand high temperatures, and water, dust, etc., do not enter the inside from the outside, so that the internal environment can be easily maintained. In addition, in the case where the sealing material 2 is composed of silicone gel, since silicone gel is transparent, it is possible to visually inspect the inside of the arm 1 after sealing, so that the inside of the arm 1 can be easily inspected.

In the case where the joining material electrically connecting the switching element 7 and the heat dissipation plate 8 is Ag, the semiconductor device 100 can be used at a higher temperature than that in the case where solder is used, so that the reliability of the semiconductor device 100 in use at high temperatures can be improved. In addition, in the case where the joining material electrically connecting the switching element 7 and the heat dissipation plate 8 is solder, since solder is a common joining material and thus inexpensive, the cost of the semiconductor device 100 can be reduced.

In the case where the power conversion device 200 includes the semiconductor device 100 described in the present embodiment, the control circuit unit 101 which controls the semiconductor device 100, and the cooler 102 which is thermally connected to the semiconductor device 100, since the semiconductor device 100 described in the present embodiment is configured such that the distance H is shortened, an increase in the size of the semiconductor device 100 is suppressed, so that an increase in the size of the power conversion device 200 using the semiconductor device 100 can be suppressed.

### Second Embodiment

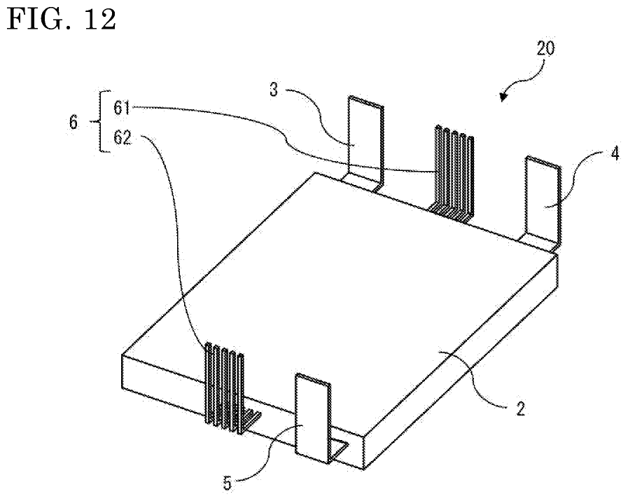

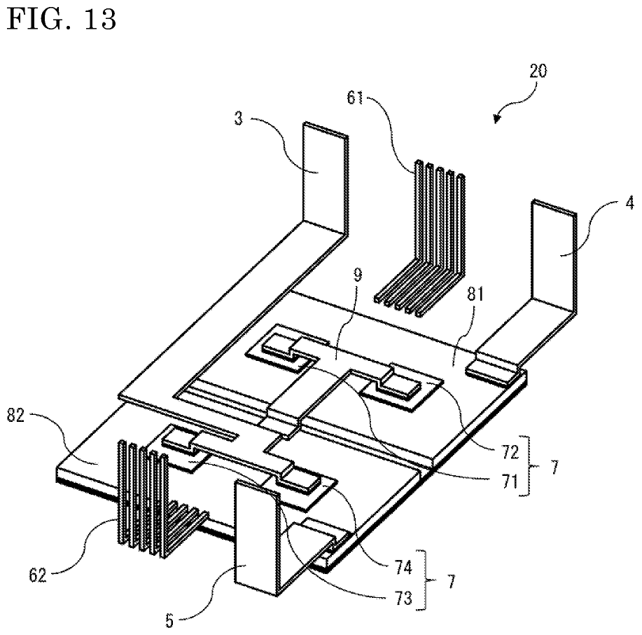

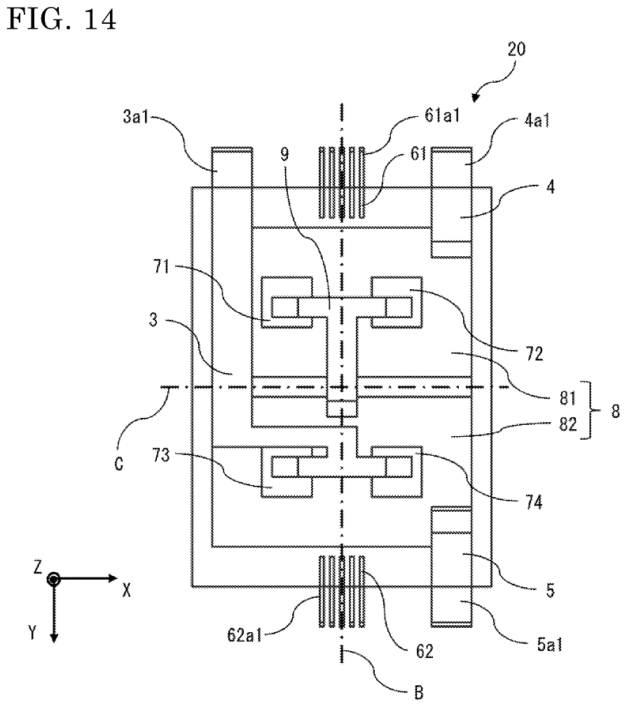

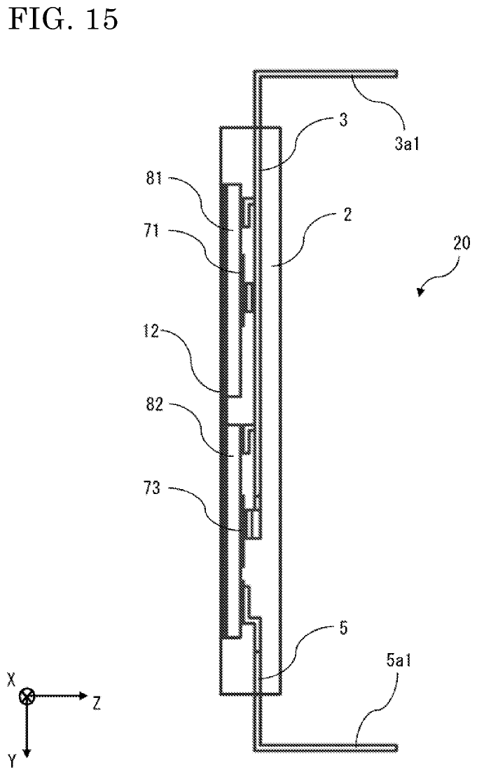

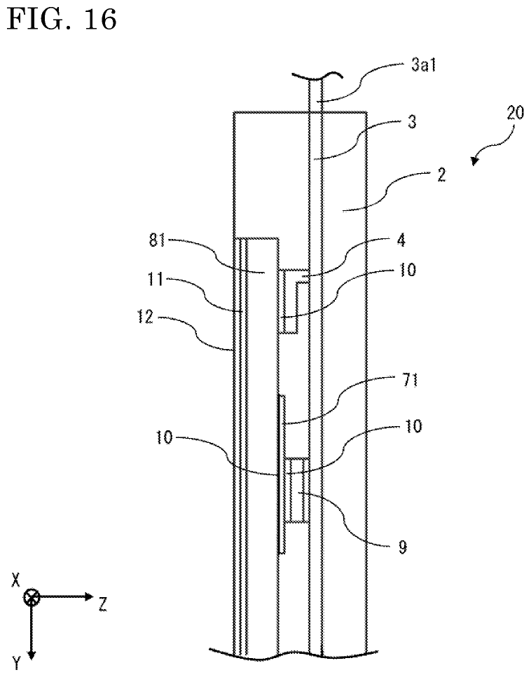

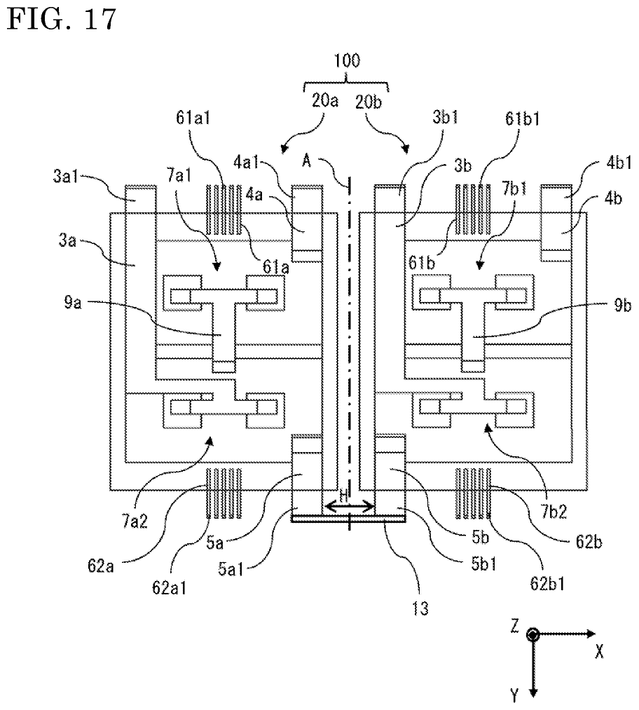

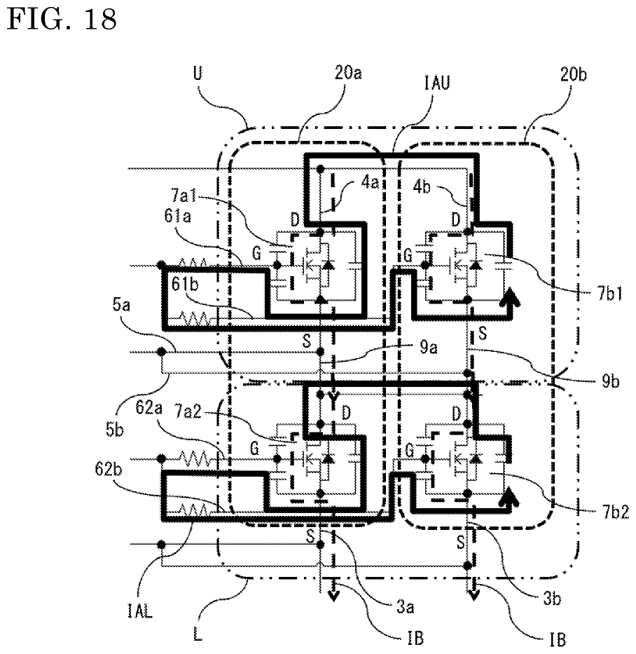

A semiconductor device 100 according to a second embodiment will be described. FIG. 12 is a perspective view showing the outer appearance of a phase arm 20 of the semiconductor device 100 according to the second embodiment; FIG. 13 is a perspective view schematically showing the configuration of the phase arm 20 of the semiconductor device 100, wherein a sealing material 2 is removed; FIG. 14 is a plan view schematically showing the configuration of the phase arm 20 of the semiconductor device 100, wherein a part of the sealing material 2 is removed; FIG. 15 is a side view schematically showing the configuration of the phase arm 20 of the semiconductor device 100, as viewed from the left side in FIG. 14, wherein a part of the sealing material 2 is removed; FIG. 16 is a side view showing a main part of the configuration of the phase arm 20 of the semiconductor device 100 and is a partially-enlarged view of FIG. 15; FIG. 17 is a plan view schematically showing the configuration of the semiconductor device 100, wherein a part of the sealing material 2 is removed; and FIG. 18 is a simplified circuit diagram of the semiconductor device 100. The semiconductor device 100 according to the second embodiment is configured to include a plurality of phase arms 20 each having two sets of arms.

<Phase Arms 20>

Each phase arm 20 included in the semiconductor device 100 will be described. The phase arm 20 has two sets of positive and negative arms, and the positive and negative arms are connected in series. The phase arm 20 is in the form called a 2-in-1 module. As shown in FIG. 12, an AC terminal 5 which is a second metal terminal, a P terminal 4 which is a fourth metal terminal, an N terminal 3 which is a third metal terminal, and a control terminal 6 are provided in the phase arm 20 so as to protrude from the sealing material 2 to the outside. In the present embodiment, the P terminal 4, the N terminal 3, and a control terminal 61 protrude from the same side surface of the sealing material 2, and the AC terminal 5 and a control terminal 62 protrude from a side surface opposite to the side surface from which the P terminal 4, the N terminal 3, and the control terminal 61 protrude. The surfaces of the sealing material 2 from which the respective terminals protrude are not limited thereto. As shown in FIG. 13, the two sets of positive and negative arms are connected by a relay terminal 9 which is a first metal terminal.

The phase arm 20 includes two sets of arms each including a heat dissipation plate 8 and one or more switching elements 7 electrically connected to one surface of the heat dissipation plate 8. In FIG. 14, the arm on the other side in the second direction is defined as an arm of a first set, and the arm on the one side in the second direction is defined as an arm of a second set. The arm of the first set is a positive arm, and the arm of the second set is a negative arm. In the present embodiment, two switching elements 71 and 72 which are switching elements of the first set connected in parallel are provided on a heat dissipation plate 81 which is a heat dissipation plate of the first set, and two switching elements 73 and 74 which are switching elements of the second set connected in parallel are provided on a heat dissipation plate 82 which is a heat dissipation plate of the second set. The number of switching elements 7 is not limited thereto. The switching element 7 and the heat dissipation plate 8 are connected, for example, by solder. The phase arm 20 further includes the N terminal 3, the P terminal 4, the AC terminal 5, the control terminal 6, the relay terminal 9, and the sealing material 2 which seals the heat dissipation plate 8, the switching element 7, the N terminal 3, the P terminal 4, the AC terminal 5, the control terminal 6, and the relay terminal 9.

The relay terminal 9 connects the surfaces of the switching elements 71 and 72 on the side opposite to the heat dissipation plate 81 side and one surface of the heat dissipation plate 82. The AC terminal 5 is connected to the one surface of the heat dissipation plate 82. The N terminal 3 is connected to the surfaces of the switching elements 73 and 74 on the side opposite to the heat dissipation plate 82 side. The P terminal 4 is connected to one surface of the heat dissipation plate 81. The control terminal 6 is connected to the switching element 7. The terminal, of the switching element 7, connected to the heat dissipation plate 8 is a drain terminal (not shown). The terminals, of the switching elements 73 and 74, which are connected to the N terminal 3, and the terminals, of the switching elements 71 and 72, which are connected to the relay terminal 9 are source terminals (not shown). The source terminals and the N terminal 3, and the source terminals and the relay terminal 9 are connected, for example, by solder. The portion, of the N terminal 3, which protrudes from the sealing material 2 is a first protruding portion 3a1, the portion, of the P terminal 4, which protrudes from the sealing material 2 is a P terminal protruding portion 4a1, the portion, of the AC terminal 5, which protrudes from the sealing material 2 is an AC terminal first protruding portion 5a1, and the portions, of the control terminal 6, which protrude from the sealing material 2 are control terminal protruding portions 61a1 and 62a1.

The heat dissipation plate 81 and the heat dissipation plate 82 are arranged on the same plane. The heat dissipation plate 81 and the heat dissipation plate 82 are provided so as to be aligned in the second direction. The switching elements 71 and 72 are arranged so as to be line-symmetric about a center line B in the first direction of the phase arm 20. The switching elements 73 and 74 are arranged so as to be line-symmetric about the center line B in the first direction of the phase arm 20. The switching elements 71 and 72 and the switching elements 73 and 74 are arranged so as to be line-symmetric about a center line C between the heat dissipation plate 81 and the heat dissipation plate 82. With this configuration, the configurations of the switching element 7 connected to the heat dissipation plate 8 is the same in the positive and negative arms, so that the productivity of the semiconductor device 100 can be improved.

The control terminal 61 and the switching elements 71 and 72 are electrically connected to each other by bonding wires (not shown). The control terminal 62 and the switching elements 73 and 74 are electrically connected to each other by bonding wires (not shown). The terminal, of the switching element 7, which is connected to the control terminal 6 is a gate terminal (not shown). As shown in FIG. 15, the phase arm 20 includes a heat dissipation sheet 12 which is thermally connected to the other surfaces of the heat dissipation plates 81 and 82 via an insulating plate 11 (not shown in FIG. 15) which is an insulating layer. The surface of the heat dissipation sheet 12 on the side opposite to the heat dissipation plate 8 side is exposed from the sealing material 2. The phase arm 20 is integrally formed, for example, by the sealing material 2 composed of mold resin.

During production of the phase arm 20, before sealing by the sealing material 2, the portions, of the N terminal 3, the P terminal 4, the AC terminal 5, and the control terminal 6, which protrude from the sealing material 2 are connected to each other, and a lead frame is formed thereon. The N terminal 3, the P terminal 4, the AC terminal 5, and the control terminal 6 are sealed by the sealing material 2 in a state of being supported by the same lead frame. After sealing, the N terminal 3, the P terminal 4, the AC terminal 5, and the control terminal 6 that are independent of each other are formed by cutting the lead frame portions thereof. The N terminal 3, the P terminal 4, AC terminal 5, and the control terminal 6 are produced by such a general production process for a semiconductor device. In the sealing process, the lead frame is held between an upper die and a lower die of a resin molding mold.

<Semiconductor Device 100>

The semiconductor device 100 including the plurality of phase arms 20 will be described. Since an increase in the output of a semiconductor device is required, a semiconductor device may be configured by using a plurality of phase arms, which are connected in parallel, for each phase of an electromagnetic induction machine which is a load. The plurality of phase arms 20 are provided on the same plane so as to be aligned in the first direction parallel to the same plane. In the present embodiment, as shown in FIG. 17, the semiconductor device 100 includes phase arms 20a and 20b which are two specific arms adjacent to each other in the first direction. The number of phase arms included in the semiconductor device 100 is not limited to two.

AC terminals 5a and 5b of the phase arms 20a and 20b have AC terminal first protruding portions 5a1 and 5b1 which are second first protruding portions which protrude from the portions of the sealing materials 2 on the one side in the second direction. The AC terminal first protruding portion 5a1 of the phase arm 20a which is one specific phase arm is arranged on the side closer to the phase arm 20, which is the other specific phase arm, than the center portion in the first direction is, at the portion of the sealing material 2 on the one side in the second direction. The AC terminal first protruding portion 5b1 of the phase arm 20b is arranged on the side closer to the phase arm 20a than the center portion in the first direction is, at the portion of the sealing material 2 on the one side in the second direction. The AC terminal first protruding portion 5a1 and the AC terminal first protruding portion 5b1 are connected to each other by a connection terminal 13. The AC terminal first protruding portions 5a1 and 5b1 and the connection terminal 13 are connected to each other, for example, by TIG welding. With this configuration, a distance H which is the length of a wire connecting the AC terminal first protruding portion 5a1 and the AC terminal first protruding portion 5b1 can be shortened. Since the distance H can be shortened, an increase in the circuit inductance between the phase arm 20a and the phase arm 20b in the semiconductor device 100 can be suppressed.

In FIG. 18, two positive arms in the semiconductor device 100 are referred to as upper arms U, and two negative arms in the semiconductor device 100 are referred to as lower arms L. In addition, in FIG. 18, current paths IAU and IAL are indicated by solid-line arrows, and current paths IB are indicated by broken-line arrows. In the phase arm 20a, the current path IB, which is a current path extending from the P terminal 4a via a drain terminal D of a switching element 7a1, passing through a source terminal S of the switching element 7a1, then extending from a relay terminal 9a via a drain terminal D of a switching element 7a2, passing through a source terminal S of the switching element 7a2, and leading to the N terminal 3a, is an ideal current path. Similarly, in the phase arm 20b as well, the current path IB is an ideal current path.

When the circuit inductance of the semiconductor device 100 is increased, a current flows through the current path IAU in the upper arm U, and a current flows through the current path IAL in the lower arm L. Therefore, no current flows through each current path IB which is an ideal current path. In the configuration shown in FIG. 17, the distance H which is the length of the wire connecting the AC terminal first protruding portion 5a1 and the AC terminal first protruding portion 5b1 can be shortened, so that an increase in the circuit inductance between the phase arm 20a and the phase arm 20b in the semiconductor device 100 can be suppressed. Since an increase in the circuit inductance is suppressed, a current easily flows through the AC terminals 5a and 5b, so that the current flowing through the current paths IAU and IAL is reduced. Since the current flowing through the current paths IAU and IAL is reduced, the switching elements 7a1, 7a2, 7b1, and 7b2 are prevented from being charged, so that the semiconductor device 100 is prevented from being destroyed. Since the semiconductor device 100 is prevented from being destroyed, the reliability of the semiconductor device 100 is improved. In addition, even if the switching characteristics of the switching elements 7a1, 7a2, 7b1, and 7b2 are different from each other, the influence on the power conversion device 200 is reduced by suppressing an increase in the circuit inductance, so that the reliability of the power conversion device 200 can be improved. In addition, since the distance H is shortened, an increase in the sizes of the semiconductor device 100 and the power conversion device 200 using the semiconductor device 100 can be suppressed.

Moreover, in the present embodiment, the AC terminal first protruding portion 5a1 of the phase arm 20a and the AC terminal first protruding portion 5b1 of the phase arm 20b are arranged so as to be line-symmetric about the center line A between the phase arms 20a and 20b. With this configuration, the distance from the center line A to the AC terminal first protruding portion 5a1 and the distance from the center line A to the AC terminal first protruding portion 5b1 are equal to each other, and the lengths of the wires at these portions are equal to each other, so that an increase in the circuit inductance of the semiconductor device 100 can be further suppressed.

Moreover, in the present embodiment, the AC terminal first protruding portion 5a1 of the phase arm 20a and the AC terminal first protruding portion 5b1 of the phase arm 20b protrude from the portions of the sealing materials 2 on the one side in the second direction, toward the one side in the second direction. With this configuration, since the AC terminals 5a and 5b do not protrude between the phase arm 20a and the phase arm 20b, the interval between the arm 1a and the arm 1b can be decreased, so that the distance H can be shortened. Since the distance H can be shortened, an increase in the circuit inductance of the semiconductor device 100 can be suppressed. The direction in which the AC terminal first protruding portions 5a1 and 5b1 protrude is not limited to the one side in the second direction, and may be the third direction. In the case where the AC terminal first protruding portions 5a1 and 5b1 protrude in the third direction as well, the interval between the phase arm 20a and the phase arm 20b can be decreased. In addition, since the interval between the phase arm 20a and the phase arm 20b is decreased and the AC terminals 5a and 5b do not protrude from both sides in the first direction, an increase in the size of the semiconductor device 100 can be suppressed.

The N terminals 3a and 3b of the phase arms 20a and 20b have first protruding portions 3a1 and 3b1 which are third first protruding portions which protrude from the portions of the sealing materials 2 on the other side in the second direction. The first protruding portions 3a1 and 3b1 protrude from the portions of the sealing materials 2 on the other side in the second direction, toward the other side in the second direction or in the third direction. In the present embodiment, the first protruding portions 3a1 and 3b1 protrude toward the other side in the second direction. With this configuration, since the N terminals 3a and 3b do not protrude between the phase arm 20a and the phase arm 20b, the interval between the phase arm 20a and the phase arm 20b can be decreased, so that the distance H can be shortened. Since the distance H can be shortened, an increase in the circuit inductance of the semiconductor device 100 can be suppressed. In addition, since the interval between the phase arm 20a and the phase arm 20b is decreased and the N terminals 3a and 3b do not protrude from both sides in the first direction, an increase in the size of the semiconductor device 100 can be suppressed.

The P terminals 4a and 4b of the phase arms 20a and 20b have P terminal protruding portions 4a1 and 4b1 which are fourth protruding portions which protrude from the portions of the sealing materials 2 on the other side in the second direction. The P terminal protruding portions 4a1 and 4b1 protrude from the portions of the sealing materials 2 on the other side in the second direction, toward the other side in the second direction or in the third direction. In the present embodiment, the P terminal protruding portions 4a1 and 4b1 protrude toward the other side in the second direction. With this configuration, since the P terminals 4a and 4b do not protrude between the phase arm 20a and the phase arm 20b, the interval between the phase arm 20a and the phase arm 20b can be decreased, so that the distance H can be shortened. Since the distance H can be shortened, an increase in the circuit inductance of the semiconductor device 100 can be suppressed. In addition, since the interval between the phase arm 20a and the phase arm 20b is decreased and the P terminals 4a and 4b do not protrude from both sides in the first direction, an increase in the size of the semiconductor device 100 can be suppressed.

Control terminals 61a and 61b have control terminal protruding portions 61a1 and 61b1 which protrude from the portions of the sealing materials 2 on the other side in the second direction, and control terminals 62a and 62b have control terminal protruding portions 62a1 and 62b1 which protrude from the portions of the sealing materials 2 on the one side in the second direction. The control terminal protruding portions 61a1 and 61b1 protrude from the portions of the sealing materials 2 on the other side in the second direction, toward the other side in the second direction or in the third direction. In the present embodiment, the control terminal protruding portions 61a1 and 61b1 protrude toward the other side in the second direction. The control terminal protruding portions 62a1 and 62b1 protrude from the portions of the sealing materials 2 on the one side in the second direction, toward the one side in the second direction or in the third direction. In the present embodiment, the control terminal protruding portions 62a1 and 62b1 protrude toward the one side in the second direction. With this configuration, since the control terminals 61a, 61b, 62a, and 62b do not protrude between the phase arm 20a and the phase arm 20b, the interval between the phase arm 20a and the phase arm 20b can be decreased, so that the distance H can be shortened. Since the distance H can be shortened, an increase in the circuit inductance of the semiconductor device 100 can be suppressed. In addition, since the interval between the phase arm 20a and the phase arm 20b is decreased and the control terminals 61a, 61b, 62a, and 62b do not protrude from both sides in the first direction, an increase in the size of the semiconductor device 100 can be suppressed.

<Modification>

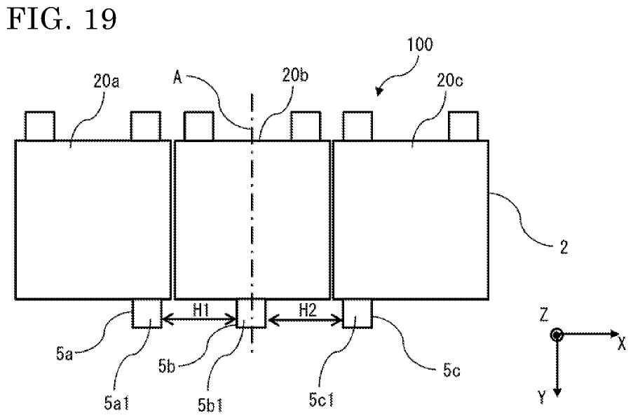

A modification of the semiconductor device 100 will be described. FIG. 19 is a plan view showing the outer appearance of another semiconductor device 100 according to the second embodiment, wherein each control terminal is not shown. In this modification, the semiconductor device 100 includes phase arms 20a, 20b, and 20c which are three specific phase arms adjacent to each other in the first direction. The specific phase arm on the one side in the first direction is the phase arm 20a, the specific phase arm on the other side in the first direction is the phase arm 20c, and the specific phase arm at the center is the phase arm 20b. The AC terminals 5a, 5b, and 5c of the phase arms 20a, 20b, and 20c have AC terminal first protruding portions 5a1, 5b1, and 5c1 which protrude from portions of sealing materials 2 on the one side in the second direction.

The AC terminal first protruding portion 5a1 of the phase arm 20a is arranged on the side closer to the phase arm 20b than the center portion in the first direction is, at the portion of the sealing material 2 on the one side in the second direction. The AC terminal first protruding portion 5c1 of the phase arm 20c is arranged on the side closer to the phase arm 20b than the center portion in the first direction is, at the portion of the sealing material 2 on the one side in the second direction. The AC terminal first protruding portion 5b1 of the phase arm 20b is arranged at the center portion in the first direction at the portion of the sealing material 2 on the one side in the second direction. With this configuration, a distance H1 which is the length of the wire connecting the AC terminal first protruding portion 5a1 and the AC terminal first protruding portion 5b1 and a distance H2 which is the length of a wire connecting the AC terminal first protruding portion 5b1 and the AC terminal first protruding portion 5c1 can be shortened. Since the distance H1 and the distance H2 can be shortened, an increase in the circuit inductance of the semiconductor device 100 can be suppressed.

Moreover, in the present embodiment, the AC terminal first protruding portion 5a1 of the phase arm 20a and the AC terminal first protruding portion 5c1 of the phase arm 20c are arranged so as to be line-symmetric about a center line A in the first direction of the phase arm 20b, and the AC terminal first protruding portion 5b1 of the phase arm 20b is arranged on the center line A. With this configuration, the distance H1 which is the length of the wire connecting the AC terminal first protruding portion 5a1 and the AC terminal first protruding portion 5b1 and the distance H2 which is the length of the wire connecting the AC terminal first protruding portion 5b1 and the AC terminal first protruding portion 5c1 can be equal to each other. Since the distance H1 and the distance H2 are equal to each other, an increase in the circuit inductance of the semiconductor device 100 can be further suppressed.

As described above, the semiconductor device 100 according to the second embodiment includes the plurality of phase arms 20 each including: two sets of arms each including the heat dissipation plate 8 and the switching element 7 electrically connected to the one surface of the heat dissipation plate 8; the relay terminal 9 connecting the surfaces of the switching elements 71 and 72 on the side opposite to the heat dissipation plate 81 side and the one surface of the heat dissipation plate 82; the AC terminal 5 connected to the one surface of the heat dissipation plate 82; and the sealing material 2 sealing these components, the heat dissipation plate 81 and the heat dissipation plate 82 are arranged on the same plane, the heat dissipation plate 81 and the heat dissipation plate 82 are provided so as to be aligned in the second direction, the plurality of phase arms are provided on the same plane so as to be aligned in the first direction, the AC terminals 5 of the two specific phase arms 20a and 20b adjacent to each other in the first direction have the AC terminal first protruding portions 5a1 and 5b1 which protrude from the portions of the sealing materials 2 on the one side in the second direction, respectively, the AC terminal first protruding portion 5a1 of the one specific phase arm 20a is arranged on the side closer to the other specific phase arm 20b than the center portion in the first direction is, at the portion of the sealing material 2 on the one side in the second direction, and the AC terminal first protruding portion 5b1 of the other specific phase arm 20b is arranged on the side closer to the one specific phase arm 20a than the center portion in the first direction is, at the portion of the sealing material 2 on the one side in the second direction. Therefore, the distance H which is the length of the wire connecting the AC terminal first protruding portion 5a1 and the AC terminal first protruding portion 5b1 can be shortened, so that an increase in the circuit inductance between the phase arm 20a and the phase arm 20b in the semiconductor device 100 can be suppressed. In addition, since the distance H is shortened, an increase in the size of the semiconductor device 100 can be suppressed.

In the case where the AC terminal first protruding portion 5a1 of the phase arm 20a and the AC terminal first protruding portion 5b1 of the phase arm 20b are arranged so as to be line-symmetric about the center line A between the phase arms 20a and 20b, the distance from the center line A to the AC terminal first protruding portion 5a1 and the distance from the center line A to the AC terminal first protruding portion 5b1 are equal to each other, and the lengths of the wires at these portions are equal to each other, so that an increase in the circuit inductance of the semiconductor device 100 can be further suppressed.

In the case where the AC terminal first protruding portions 5a1 and 5b1 of the two specific phase arms 20a and 20b protrude from the portions of the sealing materials 2 on the one side in the second direction, toward the one side in the second direction or in the third direction, since the AC terminals 5a and 5b do not protrude between the phase arm 20a and the phase arm 20b, the interval between the phase arm 20a and the phase arm 20b can be decreased, so that the distance H is shortened and an increase in the circuit inductance of the semiconductor device 100 can be suppressed. In addition, since the interval between the phase arm 20a and the phase arm 20b is decreased and the AC terminals 5a and 5b do not protrude from both sides in the first direction, an increase in the size of the semiconductor device 100 can be suppressed.

In the case where the two specific phase arms 20a and 20b include the N terminals 3a and 3b, and the first protruding portions 3a1 and 3b1 of the N terminals 3a and 3b protrude from the portions of the sealing materials 2 on the other side in the second direction, toward the other side in the second direction or in the third direction, since the N terminals 3a and 3b do not protrude between the phase arm 20a and the phase arm 20b, the interval between the phase arm 20a and the phase arm 20b can be decreased, so that the distance H is shortened and an increase in the circuit inductance of the semiconductor device 100 can be suppressed. In addition, since the interval between the phase arm 20a and the phase arm 20b is decreased and the N terminals 3a and 3b do not protrude from both sides in the first direction, an increase in the size of the semiconductor device 100 can be suppressed.

In the case where the two specific phase arms 20a and 20b include the P terminals 4a and 4b, and the P terminal protruding portions 4a1 and 4b1 of the P terminals 4a and 4b protrude from the portions of the sealing materials 2 on the other side in the second direction, toward the other side in the second direction or in the third direction, since the P terminals 4a and 4b do not protrude between the phase arm 20a and the phase arm 20b, the interval between the phase arm 20a and the phase arm 20b can be decreased, so that the distance H is shortened and an increase in the circuit inductance of the semiconductor device 100 can be suppressed. In addition, since the interval between the phase arm 20a and the phase arm 20b is decreased and the P terminals 4a and 4b do not protrude from both sides in the first direction, an increase in the size of the semiconductor device 100 can be suppressed.

In the case where the two specific phase arms 20a and 20b include the control terminals 61a, 62a, 61b, and 62b, the control terminal protruding portions 61a1 and 61b1 of the control terminals 61a and 61b protrude from the portions of the sealing materials 2 on the other side in the second direction, toward the other side in the second direction or in the third direction, and the control terminal protruding portions 62a1 and 62b1 of the control terminals 62a and 62b protrude from the portions of the sealing materials 2 on the one side in the second direction, toward the one side in the second direction or in the third direction, since the control terminals 61a, 62a, 61b, and 62b do not protrude between the phase arm 20a and the phase arm 20b, the interval between the phase arm 20a and the phase arm 20b can be decreased, so that the distance H is shortened and an increase in the circuit inductance of the semiconductor device 100 can be suppressed. In addition, since the interval between the phase arm 20a and the phase arm 20b is decreased and the control terminals 61a, 62a, 61b, and 62b do not protrude from both sides in the first direction, an increase in the size of the semiconductor device 100 can be suppressed.

In the case where: the semiconductor device 100 includes the three specific phase arms 20a, 20b, and 20c adjacent to each other in the first direction; and, when the specific phase arm on the one side in the first direction is the phase arm 20a, the specific phase arm on the other side in the first direction is the phase arm 20c, and the specific phase arm at the center is the phase arm 20b, the AC terminal first protruding portion 5a1 of the phase arm 20a is arranged on the side closer to the phase arm 20b than the center portion in the first direction is, at the portion of the sealing material 2 on the one side in the second direction, the AC terminal first protruding portion 5c1 of the phase arm 20c is arranged on the side closer to the phase arm 20b than the center portion in the first direction is, at the portion of the sealing material 2 on the one side in the second direction, and the AC terminal first protruding portion 5b1 of the phase arm 20b is arranged at the center portion in the first direction at the portion of the sealing material 2 on the one side in the second direction, the distance H1 which is the length of the wire connecting the AC terminal first protruding portion 5a1 and the AC terminal first protruding portion 5b1 and the distance H2 which is the length of the wire connecting the AC terminal first protruding portion 5b1 and the AC terminal first protruding portion 5c1 can be shortened, so that an increase in the circuit inductance of the semiconductor device 100 can be suppressed.

In the case where the AC terminal first protruding portion 5a1 of the phase arm 20a and the AC terminal first protruding portion 5c1 of the phase arm 20c are arranged so as to be line-symmetric about the center line A in the first direction of the phase arm 20b, and the AC terminal first protruding portion 5b1 of the phase arm 20b is arranged on the center line A, the distance H1 which is the length of the wire connecting the AC terminal first protruding portion 5a1 and the AC terminal first protruding portion 5b1 and the distance H2 which is the length of the wire connecting the AC terminal first protruding portion 5b1 and the AC terminal first protruding portion 5c1 can be equal to each other, so that an increase in the circuit inductance of the semiconductor device 100 can be further suppressed.

### Third Embodiment

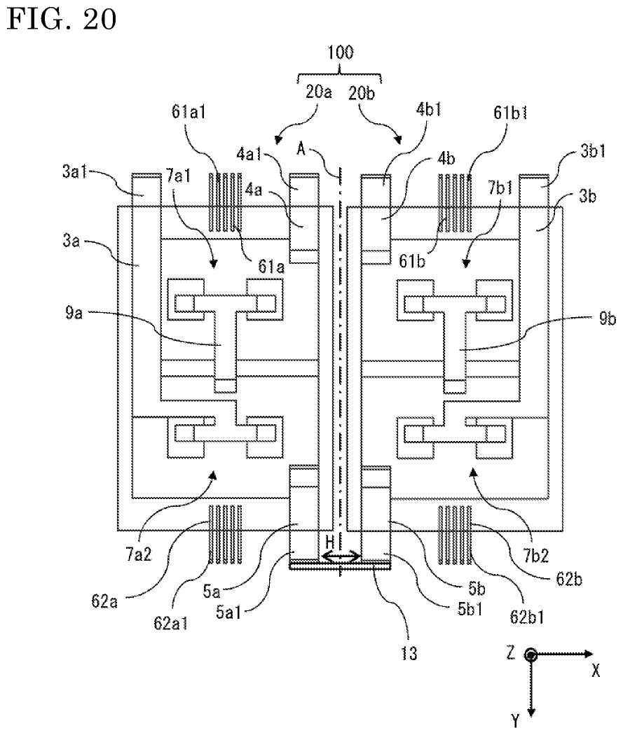

A semiconductor device 100 according to a third embodiment will be described. FIG. 20 is a plan view schematically showing the configuration of the semiconductor device 100 according to the third embodiment, wherein a part of each sealing material 2 is removed. The semiconductor device 100 according to the third embodiment has a configuration in which the arrangement of the N terminal 3b and the P terminal 4b is different from that in the second embodiment.

The N terminal 3a of the phase arm 20a and the N terminal 3b of the phase arm 20b are arranged so as to be line-symmetric about the center line A between the phase arms 20a and 20b. With this configuration, the distance from the center line A to the N terminal 3a and the distance from the center line A to the N terminal 3b are equal to each other, and the lengths of the wires connecting the N terminal 3a and the N terminal 3b are equal to each other, so that an increase in the circuit inductance of the semiconductor device 100 can be suppressed.

The P terminal 4a of the phase arm 20a and the P terminal 4b of the phase arm 20b are arranged so as to be line-symmetric about the center line A between the phase arms 20a and 20b, and the control terminals 61a and 62a of the phase arm 20a and the control terminals 61b and 62b of the phase arm 20b are arranged so as to be line-symmetric about the center line A between the phase arms 20a and 20b. With this configuration, the distance from the center line A to the P terminal 4a and the distance from the center line A to the P terminal 4b are equal to each other, and the lengths of the wires connecting the P terminal 4a and the P terminal 4b are equal to each other, so that an increase in the circuit inductance of the semiconductor device 100 can be suppressed. In addition, the distance from the center line A to the control terminal 61a and the distance from the center line A to the control terminal 61b, and the distance from the center line A to the control terminal 62a and the distance from the center line A to the control terminal 62b are equal to each other, and the lengths of the wires connecting the control terminal 61a and the control terminal 62a, and the lengths of the wires connecting the control terminal 61b and the control terminal 62b are equal to each other, so that an increase in the circuit inductance of the semiconductor device 100 can be suppressed.

In the case where the N terminals 3a and 3b, the P terminals 4a and 4b, the AC terminals 5a and 5b, and the relay terminals 9a and 9b in the phase arms 20a and 20b are all arranged so as to be line-symmetric about the center line A between the phase arms 20a and 20b, the lengths of the wires inside the phase arm 20a and the phase arm 20b are equal to each other, so that an increase in the circuit inductance of the semiconductor device 100 can be further suppressed. Even if the switching characteristics of the switching elements 7a1, 7a2, 7b1, and 7b2 are different from each other, the influence on the power conversion device 200 is reduced by suppressing an increase in the circuit inductance, so that the reliability of the power conversion device 200 can be improved.

### Fourth Embodiment

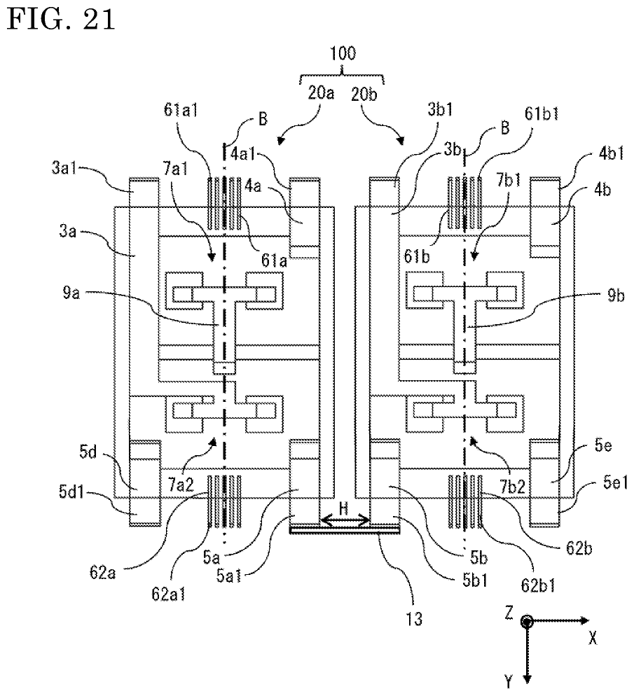

A semiconductor device 100 according to a fourth embodiment will be described. FIG. 21 is a plan view schematically showing the configuration of the semiconductor device 100 according to the fourth embodiment, wherein a part of each sealing material 2 is removed. The semiconductor device 100 according to the fourth embodiment has a configuration in which each of the phase arms 20a and 20b includes two AC terminals 5.

The phase arm 20a includes two AC terminals 5a and 5d. The phase arm 20b includes two AC terminals 5b and 5e. The AC terminal 5a of the phase arm 20a has an AC terminal first protruding portion 5a1 which protrudes from the portion of the sealing material 2 on the one side in the second direction. The AC terminal 5d of the phase arm 20a has an AC terminal second protruding portion 5d1 which is a second second protruding portion which protrudes from the portion of the sealing material 2 on the one side in the second direction. The AC terminal 5b of the phase arm 20b has an AC terminal first protruding portion 5b1 which protrudes from the portion of the sealing material 2 on the one side in the second direction. The AC terminal 5e of the phase arm 20b has an AC terminal second protruding portion 5e1 which protrudes from the portion of the sealing material 2 on the one side in the second direction. The AC terminal second protruding portion 5d1 of the phase arm 20a is arranged on the side farther from the phase arm 20b than the center portion in the first direction is, at the portion of the sealing material 2 on the one side in the second direction. The AC terminal second protruding portion 5e1 of the phase arm 20b is arranged on the side farther from the phase arm 20a than the center portion in the first direction is, at the portion of the sealing material 2 on the one side in the second direction.

In the semiconductor device 100 described in the third embodiment, the arrangements of the terminals included in the phase arms 20a and 20b are different from each other. Therefore, the phase arms 20a and 20b have to be individually produced and managed, so that the number of production steps is increased. When the semiconductor device 100 is configured as in FIG. 21, the configurations of the arrangements of the terminals included in the phase arms 20a and 20b are the same, and thus it is not necessary to individually produce and manage the phase arms 20a and 20b, so that the productivity of the phase arms 20a and 20b can be improved. In addition, the number of types of components is reduced, so that the unit costs of the components can be reduced.

Moreover, with this configuration, a current is divided and outputted from the two AC terminals 5 to the outside, and the cross-sectional area of wires at the AC terminals 5 to the outside can be increased. Since the cross-sectional areas of the wires are increased, heat generation in the AC terminals 5a, 5b, 5d, and 5e during current conduction can be suppressed.

Moreover, in the present embodiment, in the phase arm 20a, the AC terminal first protruding portion 5a1 and the AC terminal second protruding portion 5d1 are arranged so as to be line-symmetric about a center line B in the first direction of the phase arm 20a, and, in the phase arm 20b, the AC terminal first protruding portion 5b1 and the AC terminal second protruding portion 5e1 are arranged so as to be line-symmetric about a center line B in the first direction of the phase arm 20b. With this configuration, the distance from the center line B to the AC terminal first protruding portion 5a1 and the distance from the center line B to the AC terminal second protruding portion 5d1 are equal to each other, and the lengths of the wires at these portions are equal to each other, so that an increase in the circuit inductance of the semiconductor device 100 can be suppressed; and the distance from the center line B to the AC terminal first protruding portion 5b1 and the distance from the center line B to the AC terminal second protruding portion 5e1 are equal to each other, and the lengths of the wires at these portions are equal to each other, so that an increase in the circuit inductance of the semiconductor device 100 can be further suppressed.

### Fifth Embodiment

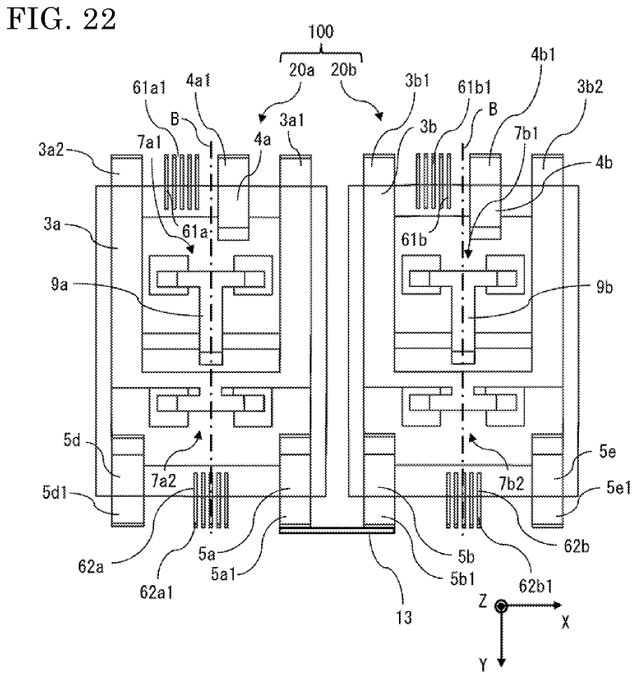

A semiconductor device 100 according to a fifth embodiment will be described. FIG. 22 is a plan view schematically showing the configuration of the semiconductor device 100 according to the fifth embodiment, wherein a part of each sealing material 2 is removed. The semiconductor device 100 according to the fifth embodiment has a configuration in which each of the N terminal 3a included in the phase arm 20a and the N terminal 3b included in the phase arm 20b branches.

The N terminal 3a of the phase arm 20a has a first protruding portion 3a1 and a second protruding portion 3a2 into which the N terminal 3a branches inside the sealing material 2 and which protrude from the portion of the sealing material 2 on the other side in the second direction, and the second protruding portion 3a2 is a third second protruding portion. The N terminal 3b of the phase arm 20b has a first protruding portion 3b1 and a second protruding portion 3b2 into which the N terminal 3b branches inside the sealing material 2 and which protrude from the portion of the sealing material 2 on the other side in the second direction, and the second protruding portion 3b2 is a third second protruding portion. The first protruding portion 3a1 of the phase arm 20a is arranged on the side closer to the phase arm 20b than the center portion in the first direction is, at the portion of the sealing material 2 on the other side in the second direction, and the first protruding portion 3b1 of the phase arm 20b is arranged on the side closer to the phase arm 20a than the center portion in the first direction is, at the portion of the sealing material 2 on the other side in the second direction. The second protruding portion 3a2 of the phase arm 20a is arranged on the side farther from the phase arm 20b than the center portion in the first direction is, at the portion of the sealing material 2 on the other side in the second direction, and the second protruding portion 3b2 of the phase arm 20b is arranged on the side farther from the phase arm 20a than the center portion in the first direction is, at the portion of the sealing material 2 on the one side in the second direction.

With this configuration, the cross-sectional areas of the wires connecting the N terminals 3a and 3b to the outside can be increased. Therefore, as compared to the configuration shown in FIG. 21, an increase in the circuit inductance between the switching element 7a2 in the N terminal 3a and the outside can be suppressed, and an increase in the circuit inductance between the switching element 7b2 in the N terminal 3b and the outside can be suppressed. Since the increase in the circuit inductance is suppressed, a current easily flows through the N terminals 3a and 3b, so that the current flowing through the current paths IAU and IAL shown in FIG. 18 is reduced. Since the current flowing through the current paths IAU and IAL is reduced, the switching elements 7a1, 7a2, 7b1, and 7b2 are prevented from being charged, so that the semiconductor device 100 is prevented from being destroyed. Since the semiconductor device 100 is prevented from being destroyed, the reliability of the semiconductor device 100 is improved. In addition, since a current is divided and flows from the N terminals 3a and 3b to the outside, and the cross-sectional areas of the wires at the N terminals 3a and 3b are increased, so that heat generation in the N terminals 3a and 3b during current conduction can be suppressed.

Moreover, in the present embodiment, in the phase arm 20a, the first protruding portion 3a1 and the second protruding portion 3a2 are arranged so as to be line-symmetric about the center line B in the first direction of the phase arm 20a, and, in the phase arm 20b, the first protruding portion 3b1 and the second protruding portion 3b2 are arranged so as to be line-symmetric about the center line B in the first direction of the phase arm 20b. With this configuration, the distance from the center line B to the first protruding portion 3a1 and the distance from the center line B to the second protruding portion 3a2 are equal to each other, and the lengths of the wires at these portions are equal to each other, so that an increase in the circuit inductance of the semiconductor device 100 can be further suppressed; and the distance from the center line B to the first protruding portion 3b1 and the distance from the center line B to the second protruding portion 3b2 are equal to each other, and the lengths of the wires at these portions are equal to each other, so that an increase in the circuit inductance of the semiconductor device 100 can be further suppressed.

Although the configurations of the 1-in-1 module and the 2-in-1 module have been described above, the configurations described in the present disclosure are not limited to the configurations of the 1-in-1 module and the 2-in-1 module. The configurations described in the present disclosure may be used for a 6-in-1 module or a 4-in-1 module.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1, 1a, 1b, 1c, 1d arm
2 sealing material
3, 3a, 3b, 3c, 3d N terminal
3a1, 3b1, 3c1, 3d1 first protruding portion
3a2, 3b2 second protruding portion
4, 4a, 4b P terminal
4a1, 4b1 P terminal protruding portion
5, 5a, 5b, 5c, 5d, 5e AC terminal
5a1, 5b1, 5c1 AC terminal first protruding portion
5d1, 5e1 AC terminal second protruding portion
6, 6a, 6b, 61, 62, 61a, 61b, 62a, 62b control terminal
6a1, 6b1, 61a1, 62a1, 61b1, 62b1 control terminal protruding portion
7, 7a, 7b, 71, 72, 73, 74, 7a1, 7a2, 7b1, 7b2 switching element
8, 8a, 8b, 81, 82 heat dissipation plate
9, 9a, 9b relay terminal
solder
11 insulating plate
12 heat dissipation sheet
13 connection terminal
20, 20a, 20b, 20c phase arm
100 semiconductor device
101 control circuit unit
102 cooler
200 power conversion device
G gate terminal
S source terminal
D drain terminal
IA, IAU, IAL, IB current path
H, H1, H2 distance
A center line
B center line
C center line
U upper arm
L lower arm

What is claimed is:

1. A semiconductor device comprising a plurality of arms each including:
a heat dissipation plate;
one or more switching elements electrically connected to one surface of the heat dissipation plate;
a metal terminal connected to a surface of each switching element on a side opposite to the heat dissipation plate side; and
a sealing material sealing the heat dissipation plate, each switching element, and the metal terminal, wherein
the heat dissipation plates of the plurality of arms are provided on a same plane so as to be aligned in a first direction which is a specific direction parallel to the same plane,
a direction which is parallel to the same plane and orthogonal to the first direction is defined as a second direction,
a direction orthogonal to the same plane is defined as a third direction,
each of the metal terminals of the two specific arms adjacent to each other in the first direction has a first protruding portion which protrudes from a portion of the sealing material on one side in the second direction,
the first protruding portion of one specific arm is arranged on a side closer to the other specific arm than a center portion in the first direction is, at the portion of the sealing material on the one side in the second direction, and
the first protruding portion of the other specific arm is arranged on a side closer to the one specific arm than a center portion in the first direction is, at the portion of the sealing material on the one side in the second direction.

2. The semiconductor device according to claim 1, wherein the first protruding portion of the one specific arm and the first protruding portion of the other specific arm are arranged so as to be line-symmetric about a center line between the two specific arms.

3. The semiconductor device according to claim 1, wherein each of the first protruding portions of the two specific arms protrudes from the portion of the sealing material on the one side in the second direction, toward the one side in the second direction or in the third direction.

4. The semiconductor device according to claim 1, wherein
each of the metal terminals of the two specific arms has the first protruding portion and a second protruding portion into which the metal terminal branches inside the sealing material and which protrude from the portion of the sealing material on the one side in the second direction,
the second protruding portion of the one specific arm is arranged on a side farther from the other specific arm than the center portion in the first direction is, at the portion of the sealing material on the one side in the second direction, and
the second protruding portion of the other specific arm is arranged on a side farther from the one specific arm than the center portion in the first direction is, at the portion of the sealing material on the one side in the second direction.

5. The semiconductor device according to claim 4, wherein the first protruding portion and the second protruding portion in each of the two specific arms are arranged so as to be line-symmetric about a center line in the first direction of the arm.

6. The semiconductor device according to claim 1, wherein
each of the two specific arms includes a heat dissipation plate metal terminal connected to the one surface of the heat dissipation plate, and a control terminal connected to the switching element,
the heat dissipation plate metal terminal has a heat dissipation plate protruding portion which protrudes from a portion of the sealing material on another side in the second direction,
the heat dissipation plate protruding portion protrudes from the portion of the sealing material on the other side in the second direction, toward the other side in the second direction or in the third direction,
the control terminal has a control terminal protruding portion which protrudes from the portion of the sealing material on the other side in the second direction, and
the control terminal protruding portion protrudes from the portion of the sealing material on the other side in the second direction, toward the other side in the second direction or in the third direction.

7. The semiconductor device according to claim 6, wherein
the heat dissipation plate metal terminal of the one specific arm and the heat dissipation plate metal terminal of the other specific arm are arranged so as to be line-symmetric about the center line between the two specific arms, and
the control terminal of the one specific arm and the control terminal of the other specific arm are arranged so as to be line-symmetric about the center line between the two specific arms.

8. A semiconductor device comprising a plurality of arms each including:
a heat dissipation plate;
one or more switching elements electrically connected to one surface of the heat dissipation plate;
a metal terminal connected to a surface of each switching element on a side opposite to the heat dissipation plate side; and
a sealing material sealing the heat dissipation plate, each switching element, and the metal terminal, wherein
the heat dissipation plates of the plurality of arms are provided on a same plane so as to be aligned in a first direction which is a specific direction parallel to the same plane,
a direction which is parallel to the same plane and orthogonal to the first direction is defined as a second direction,
a direction orthogonal to the same plane is defined as a third direction,
each of the metal terminals of the three specific arms adjacent to each other in the first direction has a first protruding portion which protrudes from a portion of the sealing material on one side in the second direction,
the first protruding portion of the specific arm on one side in the first direction is arranged on a side closer to the specific arm at a center than a center portion in the first direction is, at the portion of the sealing material on the one side in the second direction,
the first protruding portion of the specific arm on another side in the first direction is arranged on a side closer to the specific arm at the center than a center portion in the first direction is, at the portion of the sealing material on the one side in the second direction, and
the first protruding portion of the specific arm at the center is arranged at a center portion in the first direction at the portion of the sealing material on the one side in the second direction.

9. The semiconductor device according to claim 8, wherein
the first protruding portion of the specific arm on the one side in the first direction and the first protruding portion of the specific arm on the other side in the first direction are arranged so as to be line-symmetric about a center line in the first direction of the specific arm at the center, and
the first protruding portion of the specific arm at the center is arranged on the center line.

10. A semiconductor device comprising a plurality of phase arms each including:
two sets of arms each including a heat dissipation plate and one or more switching elements electrically connected to one surface of the heat dissipation plate;
a first metal terminal connecting a surface of each switching element of a first set on a side opposite to a side of the heat dissipation plate of the first set and one surface of the heat dissipation plate of a second set;
a second metal terminal connected to the one surface of the heat dissipation plate of the second set; and
a sealing material sealing the heat dissipation plate, each switching element, the first metal terminal, and the second metal terminal, wherein
the heat dissipation plate of the first set and the heat dissipation plate of the second set are arranged on a same plane,
a direction parallel to the same plane is defined as a first direction,
a direction which is parallel to the same plane and orthogonal to the first direction is defined as a second direction,
a direction orthogonal to the same plane is defined as a third direction,
the heat dissipation plate of the first set and the heat dissipation plate of the second set are provided so as to be aligned in the second direction,
the plurality of phase arms are provided on the same plane so as to be aligned in the first direction,
each of the second metal terminals of the two specific phase arms adjacent to each other in the first direction has a second first protruding portion which protrudes from a portion of the sealing material on one side in the second direction,
the second first protruding portion of one specific phase arm is arranged on a side closer to the other specific phase arm than a center portion in the first direction is, at the portion of the sealing material on the one side in the second direction, and
the second first protruding portion of the other specific phase arm is arranged on a side closer to the one specific phase arm than a center portion in the first direction is, at the portion of the sealing material on the one side in the second direction.

11. The semiconductor device according to claim 10, wherein the second first protruding portion of the one specific phase arm and the second first protruding portion of the other specific phase arm are arranged so as to be line-symmetric about a center line between the two specific phase arms.

12. The semiconductor device according to claim 10, wherein each of the second first protruding portions of the two specific phase arms protrudes from the portion of the sealing material on the one side in the second direction, toward the one side in the second direction or in the third direction.

13. The semiconductor device according to claim 10, wherein
each of the two specific phase arms includes the two second metal terminals,
in each of the two specific phase arms, one second metal terminal has the second first protruding portion which protrudes from the portion of the sealing material on the one side in the second direction, and the other second metal terminal has a second protruding portion which protrudes from the portion of the sealing material on the one side in the second direction,
the second protruding portion of the one specific phase arm is arranged on a side farther from the other specific phase arm than the center portion in the first direction is, at the portion of the sealing material on the one side in the second direction, and
the second protruding portion of the other specific phase arm is arranged on a side farther from the one specific phase arm than the center portion in the first direction is, at the portion of the sealing material on the one side in the second direction.

14. The semiconductor device according to claim 13, wherein the second first protruding portion and the second protruding portion in each of the two specific phase arms are arranged so as to be line-symmetric about a center line in the first direction of the phase arm.

15. The semiconductor device according to claim 10, wherein
each of the two specific phase arms includes a third metal terminal connected to a surface of each switching element of the second set on a side opposite to a side of the heat dissipation plate of the second set,
the third metal terminal has a third first protruding portion which protrudes from a portion of the sealing material on another side in the second direction, and
the third first protruding portion protrudes from the portion of the sealing material on the other side in the second direction, toward the other side in the second direction or in the third direction.

16. The semiconductor device according to claim 15, wherein the third metal terminal of the one specific phase arm and the third metal terminal of the other specific phase arm are arranged so as to be line-symmetric about the center line between the two specific phase arms.

17. The semiconductor device according to claim 15, wherein
each of the third metal terminals of the two specific phase arms has the third first protruding portion and a third second protruding portion into which the third metal terminal branches inside the sealing material and which protrude from the portion of the sealing material on the other side in the second direction,
the third first protruding portion of the one specific phase arm is arranged on a side closer to the other specific phase arm than a center portion in the first direction is, at the portion of the sealing material on the other side in the second direction,
the third first protruding portion of the other specific phase arm is arranged on a side closer to the one specific phase arm than a center portion in the first direction is, at the portion of the sealing material on the other side in the second direction,
the third second protruding portion of the one specific phase arm is arranged on a side farther from the other specific phase arm than the center portion in the first direction is, at the portion of the sealing material on the other side in the second direction, and
the third second protruding portion of the other specific phase arm is arranged on a side farther from the one specific phase arm than the center portion in the first direction is, at the portion of the sealing material on the one side in the second direction.

18. The semiconductor device according to claim 17, wherein the third first protruding portion and the third second protruding portion in each of the two specific phase arms are arranged so as to be line-symmetric about the center line in the first direction of the arm.

19. The semiconductor device according to claim 10, wherein
each of the two specific phase arms includes a fourth metal terminal connected to one surface of the heat dissipation plate of the first set, and a control terminal connected to each switching element,
the fourth metal terminal has a fourth protruding portion which protrudes from the portion of the sealing material on the other side in the second direction,
the fourth protruding portion protrudes from the portion of the sealing material on the other side in the second direction, toward the other side in the second direction or in the third direction,
the control terminal has a control terminal protruding portion which protrudes from the portions of the sealing material on the one side and the other side in the second direction, and
the control terminal protruding portion protrudes from the portions of the sealing material on the one side and the other side in the second direction, toward the one side and the other side in the second direction or in the third direction.

20. The semiconductor device according to claim 19, wherein
the fourth metal terminal of the one specific phase arm and the fourth metal terminal of the other specific phase arm are arranged so as to be line-symmetric about the center line between the two specific phase arms, and
the control terminal of the one specific phase arm and the control terminal of the other specific phase arm are arranged so as to be line-symmetric about the center line between the two specific phase arms.

21. A semiconductor device comprising a plurality of phase arms each including:
two sets of arms each including a heat dissipation plate and one or more switching elements electrically connected to one surface of the heat dissipation plate;
a first metal terminal connecting a surface of each switching element of a first set on a side opposite to a side of the heat dissipation plate of the first set and one surface of the heat dissipation plate of a second set;
a second metal terminal connected to the one surface of the heat dissipation plate of the second set; and
a sealing material sealing the heat dissipation plate, each switching element, the first metal terminal, and the second metal terminal, wherein
the heat dissipation plate of the first set and the heat dissipation plate of the second set are arranged on a same plane,
a direction parallel to the same plane is defined as a first direction,
a direction which is parallel to the same plane and orthogonal to the first direction is defined as a second direction,
a direction orthogonal to the same plane is defined as a third direction,
the heat dissipation plate of the first set and the heat dissipation plate of the second set are provided so as to be aligned in the second direction,
the plurality of phase arms are provided on the same plane so as to be aligned in the first direction,
each of the second metal terminals of the three specific phase arms adjacent to each other in the first direction has a second first protruding portion which protrudes from a portion of the sealing material on one side in the second direction,
the second first protruding portion of the specific phase arm on one side in the first direction is arranged on a side closer to the specific phase arm at a center than a center portion in the first direction is, at the portion of the sealing material on the one side in the second direction,
the second first protruding portion of the specific phase arm on another side in the first direction is arranged on a side closer to the specific phase arm at the center than a center portion in the first direction is, at the portion of the sealing material on the one side in the second direction, and
the second first protruding portion of the specific phase arm at the center is arranged at a center portion in the first direction at the portion of the sealing material on the one side in the second direction.

22. The semiconductor device according to claim 21, wherein
the second first protruding portion of the specific phase arm on the one side in the first direction and the second first protruding portion of the specific phase arm on the other side in the first direction are arranged so as to be line-symmetric about a center line in the first direction of the specific phase arm at the center, and
the second first protruding portion of the specific phase arm at the center is arranged on the center line.

23. The semiconductor device according to claim 1, further comprising a heat dissipation sheet thermally connected to another surface of the heat dissipation plate via an insulating layer, wherein
a surface of the heat dissipation sheet on a side opposite to the heat dissipation plate side is exposed from the sealing material.

24. The semiconductor device according to claim 1, wherein the sealing material is composed of mold resin or silicone gel.

25. The semiconductor device according to claim 1, wherein a joining material electrically connecting each switching element and the heat dissipation plate is Ag or solder.

26. A power conversion device comprising:
the semiconductor device according to claim 1;
a control circuit unit which controls the semiconductor device; and
a cooler which is thermally connected to the semiconductor device.
